(19) United States
(12) Patent Application Publication
(10) Pub. No.: US 2025/0243691 A1
(43) Pub. Date: Jul. 31, 2025

(54) ELECTRONIC LOCK WITH INTERCHANGEABLE BATTERY PACKS HAVING DIFFERENT BATTERY CHEMISTRIES

(71) Applicant: ASSA ABLOY Americas Residential Inc., New Haven, CT (US)

(72) Inventors: Kevin Pasma, Lake Forest, CA (US); Kevin Coleman, Lake Forest, CA (US); Corey Coolidge, Foothill Ranch, CA (US); Alan Uyeda, Irvine, CA (US)

(21) Appl. No.: 19/037,722

(22) Filed: Jan. 27, 2025

Related U.S. Application Data
(60) Provisional application No. 63/627,546, filed on Jan. 31, 2024.

(51) Int. Cl. E05B 47/00; G01R 31/36

(52) U.S. Cl. CPC E05B 47/0001; G01R 31/3647; E05B 2047/0058; E05B 2047/0067; E05B 2047/0095; E05B 2047/0097

(57) ABSTRACT

An electronic lock is disclosed. The electronic lock may be compatible with battery packs having different chemistries. In an example, the electronic lock may be compatible with both alkaline battery packs and lithium battery packs. In some embodiments, operation of the electronic lock is based on the chemistry of the battery pack. Examples of operations of the electronic lock that may be based on the chemistry of the battery pack include operation of a motor for moving a bolt between an extended position and a retracted position, low-power mode operations, and processes for determining a remaining power of the battery pack.

### CROSS-REFERENCE TO RELATED APPLICATIONS

This application claims priority to U.S. Provisional Patent Application No. 63/627,546 filed Jan. 31, 2024, the disclosure of which is incorporated herein by reference in its entirety.

### TECHNICAL FIELD

This invention relates to the field of electronic lock. More particularly, this invention relates to electronic locks with interchangeable battery packs having different battery chemistries.

### BACKGROUND

Some locks may include electrical components. For example, a lock may include electrical components for actuating a locking mechanism, communicating with other devices, communicating with users, storing data, or performing other functions. The electrical components consume power from a power source, typically a stored power source such as a battery.

Batteries may include electrochemical cells of different chemistries. These different chemistries may provide different advantages based on the chemistry. For example, batteries of certain chemistries may have higher voltages or be rechargeable.

Typically, electronic locks are designed to be used with batteries having a particular chemistry, as they are tuned to have particular voltage and power consumption requirements. For example, a motor used to drive a bolt of the electronic lock may be selected to operate in response to a supply of voltage and current at predetermined levels.

### SUMMARY

In general, aspects of the present disclosure relate to an electronic lock with interchangeable battery packs having different battery chemistries. Based on the chemistry of the attached battery pack, the electronic lock may operate differently. Differences in behavior may include, but are not limited to, differences in operation of a motor control, differences in the way remaining battery power is calculated, and/or differences in recommended lock settings based on historical usage patterns.

In a first aspect, an electronic lock is provided. The electronic lock comprises an interior assembly including one or more electrical pins, at least one processor, and a memory. The electrical pins are configured to electrically connect the electronic lock to a battery pack. The memory is communicatively connected to the at least one processor and stores instructions that, when executed, cause the electronic lock to determine a chemistry of the battery pack and select an operating mode from a plurality of operating modes based on the chemistry of the battery pack. Each of the plurality of operating modes is associated with a battery pack chemistry.

In a second aspect, a method of operating an electronic lock is provided. The method comprises determining a chemistry of a battery pack of the electronic lock based on a sensed signal associated with the battery pack and selecting an operating mode of the electronic lock from among a plurality of operating modes based on the chemistry of the battery pack. Each of the plurality of operating modes is associated with a battery pack chemistry.

In a third aspect, a removable battery pack for an electronic lock is provided. The battery pack comprises one or more batteries, a connector, and one or more contacts. The connector is configured to removably attach the battery pack to the electronic lock. The one or more contacts are electrically connectable to one or more pins on the electronic lock. A chemistry of the battery is used to determine an operating mode of the electronic lock.

### BRIEF DESCRIPTION OF THE DRAWINGS

The following drawings are illustrative of particular embodiments of the present disclosure and therefore do not limit the scope of the present disclosure. The drawings are not to scale and are intended for use in conjunction with the explanations in the following detailed description. Embodiments of the present disclosure will hereinafter be described in conjunction with the appended drawings, wherein like numerals denote like elements.

FIG. 1 illustrates an environment including an electronic lock in which aspects of the present disclosure may be implemented.

FIG. 2 illustrates an environment including an electronic lock in which aspects of the present disclosure may be implemented.

FIG. 3 illustrates a side view of a portion of an electronic lock usable within the environments of FIGS. 1 and 2.

FIG. 4 illustrates a rear perspective view of a portion of an electronic lock usable within the environments of FIGS. 1 and 2.

FIG. 5 illustrates a rear perspective view of a portion of an electronic lock usable within the environments of FIGS. 1 and 2.

FIG. 6 illustrates a front perspective view of a portion of an electronic lock usable within the environments of FIGS. 1 and 2.

FIG. 7 illustrates a schematic representation of an electronic lock, in accordance with aspects of the present disclosure.

FIG. 8 illustrates a rear perspective view of a battery pack compatible with an electronic lock.

FIG. 9 illustrates an exploded view of a battery pack compatible with an electronic lock.

FIG. 10 illustrates a front view of a battery pack compatible with an electronic lock.

FIG. 11 illustrates a cross-sectional view of a battery pack compatible with an electronic lock.

FIG. 12 illustrates a front perspective view of a battery pack compatible with an electronic lock.

FIG. 13 illustrates a rear perspective view of a battery pack compatible with an electronic lock.

FIG. 14 illustrates an exploded view of a battery pack compatible with an electronic lock.

FIG. 15 illustrates a cross-sectional view of a battery pack compatible with an electronic lock.

FIG. 16 illustrates a close-up view of contacts of a battery pack compatible with an electronic lock.

FIG. 17 illustrates a bottom view of a battery pack compatible with an electronic lock.

FIG. 18 illustrates a schematic representation of a mobile device seen in the environment of FIG. 2.

FIG. 19 is a flowchart of a method for controlling operation of an electronic lock based on a chemistry of an attached battery pack.

FIG. 20 is a flowchart of a method for determining a chemistry of a battery pack attached to an electronic lock.

FIG. 21 is a flowchart of a method for determining a chemistry of a battery pack attached to an electronic lock.

FIG. 22 is a flowchart of operation of an electronic lock in a first operation mode to assess whether to recommend a change in chemistry of a battery pack.

### DETAILED DESCRIPTION

Various embodiments of the present invention will be described in detail with reference to the drawings, wherein like reference numerals represent like parts and assemblies throughout the several views. Reference to various embodiments does not limit the scope of the invention, which is limited only by the scope of the claims attached hereto. Additionally, any examples set forth in this specification are not intended to be limiting and merely set forth some of the many possible embodiments for the claimed invention.

As briefly described above, embodiments of the present invention relate to an electronic lock that is useable with battery packs that are interchangeable and having different battery chemistries. In some embodiments, a processor in the electronic lock determines a chemistry of an attached battery pack, and the processor controls aspects of the electronic lock based on the chemistry of the attached battery pack. For example, a battery capacity estimate process may differ based on the chemistry of the attached battery pack. In another example, operation of electrical components within the electronic lock (e.g., a motor) may differ based on the chemistry of the attached battery pack.

In examples described herein, interchangeable battery packs have an alkaline chemistry or a lithium-ion chemistry. It is understood that the electronic lock described herein is not limited to operate solely with alkaline and lithium battery packs, and alternative battery chemistries can be used.

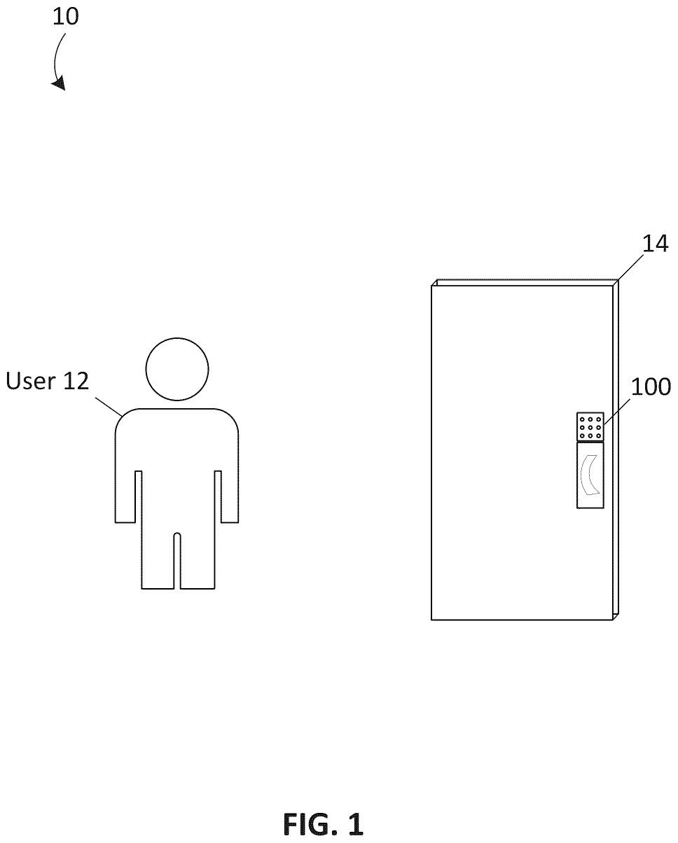

FIG. 1 illustrates an environment 10 in which aspects of the present disclosure may be implemented. A door 14 comprising an electronic lock 100 (also referred to as a wireless electronic lock) is installed at a premises. In some embodiments, the electronic lock 100 may include wireless communication capabilities. For example, the electronic lock 100 may include components for communicating with a user 12. In some embodiments, the electronic lock 100 may not include wireless communication capabilities. In particular, in some embodiments, electronic lock 100 may lack any communication capabilities, and its electronics are limited to actuation of a motor for lock operation locally.

A user 12 may interact with the electronic lock 100 to, for example, actuate a locking mechanism, check a status of the lock, update a lock setting, or perform another operation related to the lock 100. In some instances, the user 12 may be registered with the electronic lock 100 or may otherwise be authorized to actuate the electronic lock 100, such as an owner or tenant of the premises where the door 14 comprising the electronic lock 100 is installed. In some instances, the user 12 may have a code that he or she may enter at a keypad of the electronic lock 100 to actuate the locking mechanism, either in addition to or to the exclusion of the user being otherwise registered or authorized at the electronic lock 100 (e.g., via connectivity between a mobile device of the user 12 and the electronic lock 100).

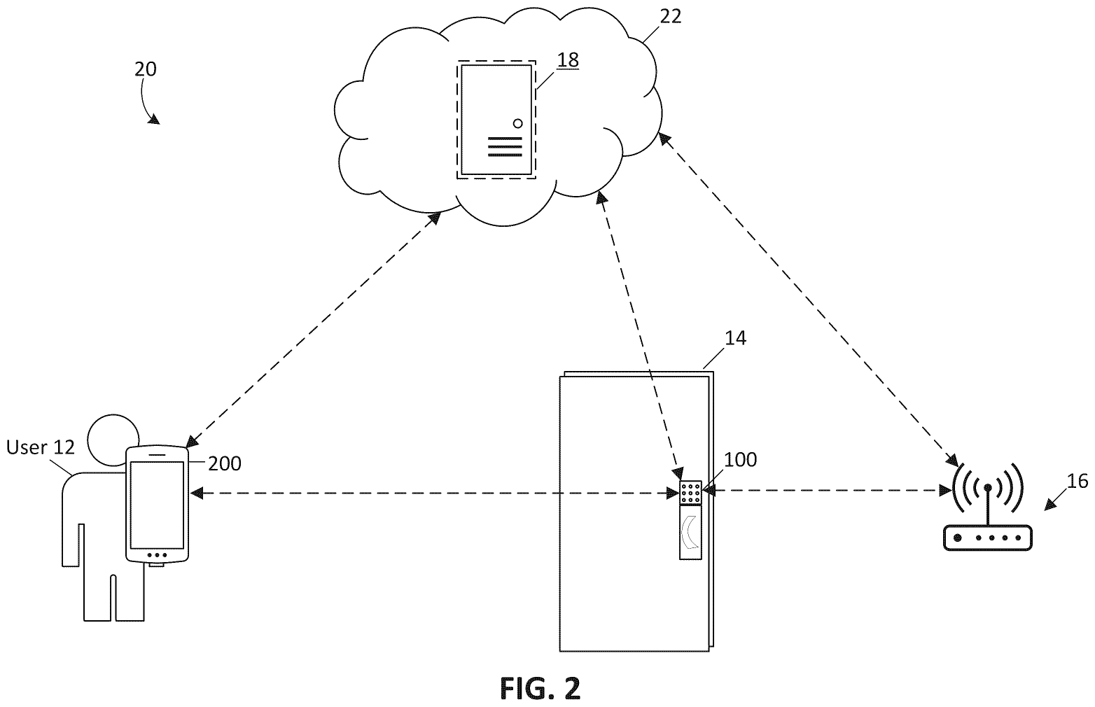

FIG. 2 illustrates an alternative environment 20 in which aspects of the present disclosure may be implemented. The environment 20 includes the user 12, a mobile device 200, the door 14, the electronic lock 100, a wireless router 16, and a server 18.

In the example shown, the user 12 may be associated with the mobile device 200. For example, the user 12 may carry the mobile device 200 or be the owner of the mobile device 200. The mobile device 200 may be a device with wireless communication capabilities, such as a smartphone, tablet, or key fob. The mobile device 200 may be capable of communicating with the electronic lock 100, communicating with the server 18, communicating with other mobile devices, and communicating with the router 16. The mobile device 200 may have a mobile application installed thereon that is associated with the electronic lock 100 or the server 18. The mobile device 200 may include a web browser for accessing a program to communicate with the electronic lock 100 or the server 18.

The server 18 can be, for example, a physical server or a virtual server hosted on a cloud platform 22. In examples, the cloud platform 22 may be a multi-cloud platform, a private cloud, a public cloud, or a hybrid cloud. In some embodiments, the server 18 may include a cluster of servers or nodes. In some embodiments, the electronic lock 100 is also capable of communicating with the server 18. Such communication can optionally occur via one or more wireless communication protocols, e.g., Wi-Fi (IEEE 802.11), short-range wireless communication to a Wi-Fi bridge, or other connection mechanism. According to an embodiment, the server 18 may create and store an account associated with one or more of the electronic lock 100, the user 12, the mobile device 200, the router 16, the door 14, or the building on which the door 14 is installed. In some embodiments, the server 18 may create or store credentials for one or more of the accounts.

The router 16 may be a Wi-Fi router. In some embodiments, the router 16 be located within the premises or building to which the door 14 is attached. The router 16 may be capable of communicating with the electronic lock 100, and the router 16 may be capable of communicating with the server 18. The router 16 may route communications between the server 18 and the electronic lock 100. In some embodiments, the router 16 may be a hub for Internet of Things (IoT) devices. In some embodiments, the electronic lock 100 and the router 16 may be coupled via a mesh network. For instance, communication between the electronic lock 100 and the router 16 may be passed through one or more other devices.

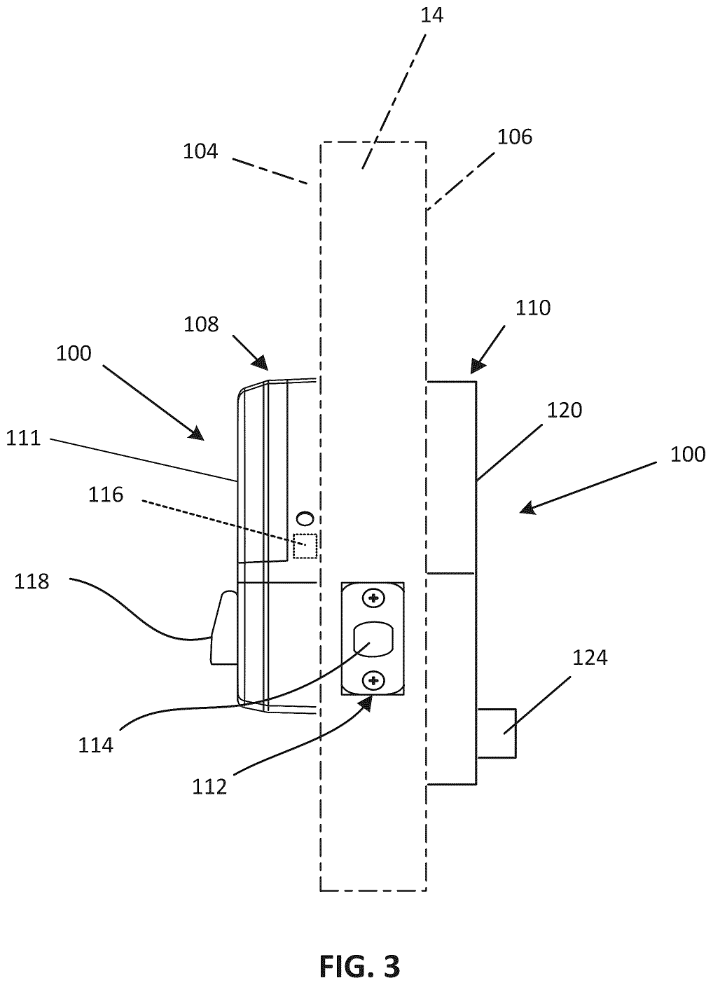

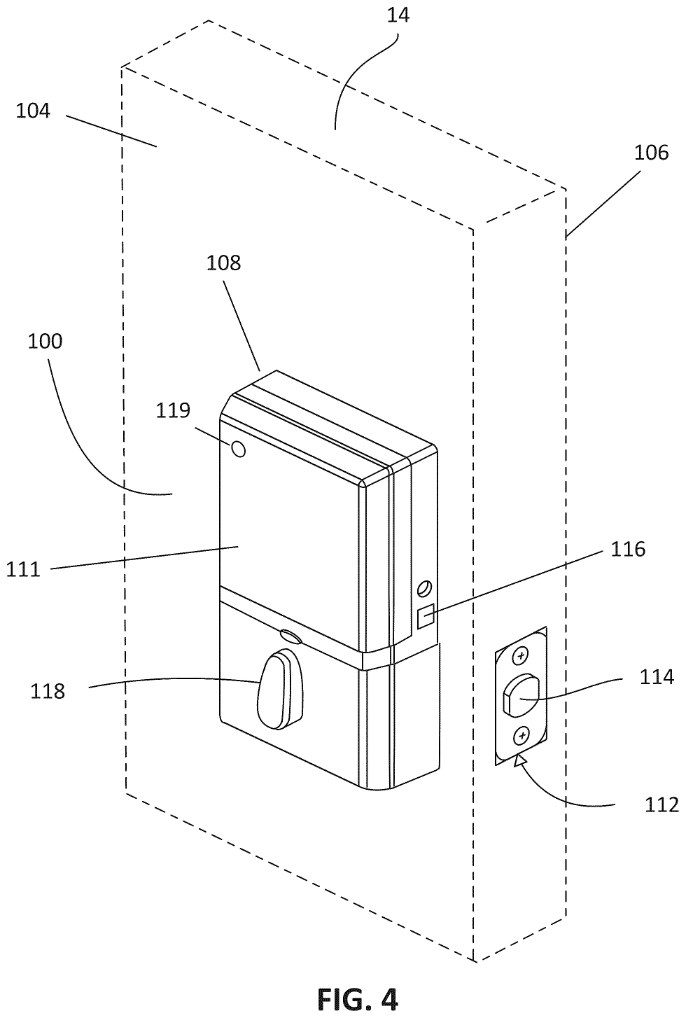

Referring to FIGS. 3-8 generally, in example embodiments, the electronic lock 100 may be used on both interior and exterior doors. Described below are non-limiting examples of a wireless electronic lock 100. It should be noted that the electronic lock 100 may be used on other types of doors, such as a garage door or a doggie door, or other types of doors that require an authentication process to unlock (or lock) the door.

FIGS. 3-6 illustrate an electronic lock 100 as installed at a door 14, according to one example of the present disclosure. The door 14 has an interior side 104 and an exterior side 106. The electronic lock 100 includes an interior assembly 108, an exterior assembly 110, and a latch assembly 112. The latch assembly 112 is shown to include a bolt 114 that is movable between an extended position (locked) and a retracted position (unlocked, shown in FIGS. 3-6). Specifically, the bolt 114 is configured to slide longitudinally and, when the bolt 114 is retracted, the door 14 is in an unlocked state. When the bolt 114 is extended, the bolt 114 protrudes from the door 14 into a doorjamb (not shown) to place the door 14 in a locked state. In examples, a processor of the electronic lock 100 may use a motor to actuate the bolt 114.

In some examples, the interior assembly 108 is mounted to the interior side 104 of the door 14, and the exterior assembly 110 is mounted to the exterior side 106 of the door 14. The latch assembly 112 is typically at least partially mounted in a bore formed in the door 14. The term “outside” is broadly used to mean an area outside the door 14 and “inside” is broadly used to denote an area inside the door 14. With an exterior entry door, for example, the exterior assembly 110 may be mounted outside a building, while the interior assembly 108 may be mounted inside the building. With an interior door, the exterior assembly 110 may be mounted inside a building, but outside a room secured by the electronic lock 100, and the interior assembly 108 may be mounted inside the secured room. The electronic lock 100 is applicable to both interior and exterior doors.

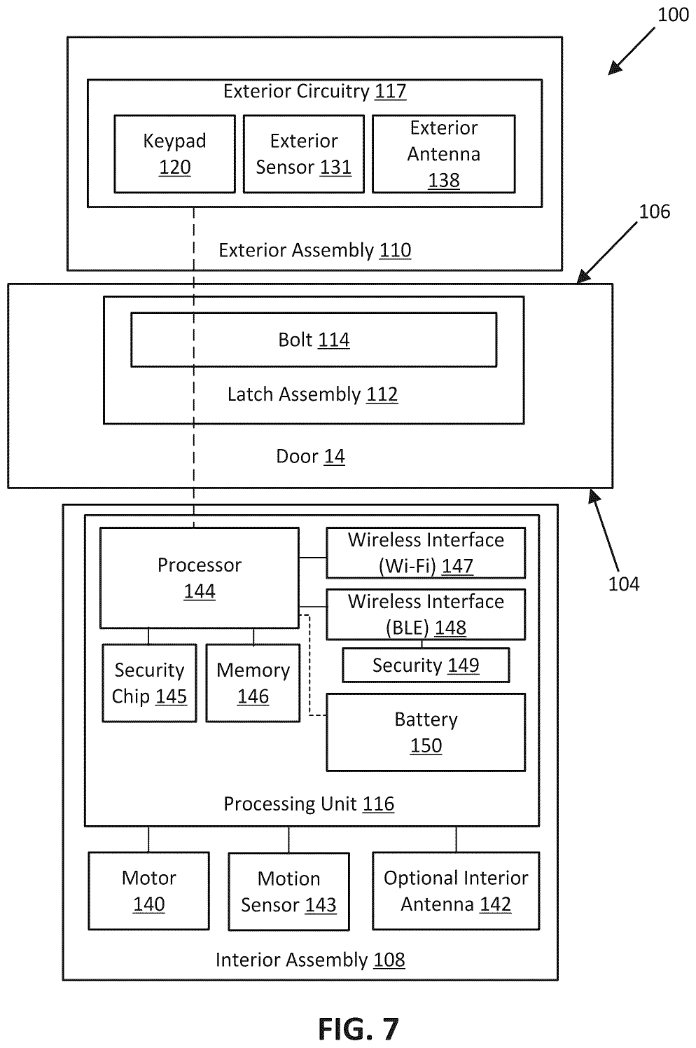

In some embodiments, the interior assembly 108 can include a processing unit 116 (shown schematically in FIG. 7) containing electronic circuitry for the electronic lock 100. In some examples, the interior assembly 108 includes a manual turn piece 118 that can be used on the interior side 104 of door 14 to move the bolt 114 between the extended and retracted positions. The processing unit 116 is operable to execute a plurality of software instructions (e.g., firmware) that, when executed by the processing unit 116, cause the electronic lock 100 to implement the methods and otherwise operate and have functionality as described herein. The processing unit 116 may comprise a device commonly referred to as a processor, e.g., a central processing unit (CPU), digital signal processor (DSP), or other similar device, and may be embodied as a standalone unit or as a device shared with components of the electronic lock 100. The processing unit 116 may include memory communicatively interfaced to the processor for storing the software instructions. Alternatively, the electronic lock 100 may further comprise a separate memory device for storing the software instructions that is electrically connected to the processing unit 116 for the bi-directional communication of the instructions, data, and signals therebetween.

In some examples, the interior assembly 108 includes a pairing button 119 (shown schematically), which when actuated, initiates a pairing mode for a connection over an interface. For example, the pairing mode may enable the electronic lock 100 to communicate with a mobile device (e.g., the mobile device 200) within wireless communication range for enabling the mobile device to be paired with the electronic lock 100. As can be appreciated, initiating the pairing mode via an actuation of the pairing button 119 may be limited to users who have access to the interior side 104 of the door 14. In some embodiments, the electronic lock 100 may be coupled with a mobile device without use of the pairing button 119. For instance, pairing may be performed by communicating with the server 18, or one or more of the mobile device 200 or the electronic lock 100 may broadcast a signal for pairing.

In some examples, a battery pack is installed within the interior assembly 108 and is housed within the interior assembly 108 by a cover 111. As described herein, the electronic lock 100 is compatible with battery packs of different chemistries—e.g., alkaline battery packs and lithium battery packs. In some embodiments, battery packs of different chemistries may have different sizes. For example, an alkaline battery pack may be smaller than a lithium battery pack. In such embodiments, the cover 111 may have dimensions compatible with battery packs of different sizes. Alternatively, in some embodiments, the electronic lock 100 may have multiple covers 111, and each cover 111 may be associated with a specific battery pack chemistry such that when the battery pack is replaced with a battery pack of a different chemistry, the cover 111 is also replaced to accommodate a different size battery pack. Further, the electronic lock 100 may have multiple covers 111 for battery packs of different capacities, regardless of whether the battery chemistry differs. For example, a lithium battery pack with a larger capacity may require a different cover 111 than a lithium battery pack with a smaller capacity.

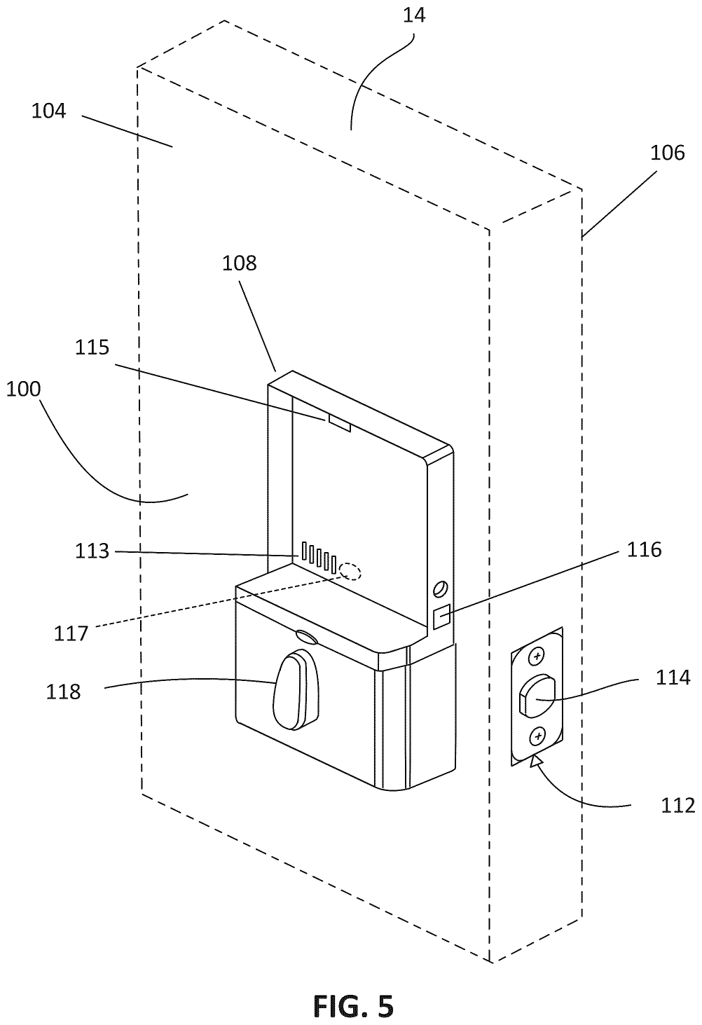

FIG. 5 illustrates an embodiment of the interior assembly 108 with the cover 111 removed to show a compartment in which the battery pack is housed. In embodiments, a latch 115 interacts with the battery pack to removably attach the battery pack to the electronic lock 100. In alternative embodiments, different attachment mechanisms are used to removably attach the battery pack to the electronic lock 100, including other types of mechanical fasteners.

One or more pins 113 electrically connect the battery pack to the processing unit 116 and other electrical components of the electronic lock 100. The pins 113 are configured to connect with multiple battery packs of different chemistries. In an example, the pins 113 connect to contacts on the battery pack. In alternative embodiments, the electronic lock 100 includes contacts that connect to pins on the battery pack. In example implementations, battery packs designed using a first chemistry (e.g., lithium ion) may utilize a different number of pins 113 as compared to battery packs using a second chemistry (e.g., alkaline). For example, an alkaline battery pack may use two electrical connections, or pins 113, corresponding to positive and negative voltage pins. A lithium-ion battery pack, however, may include positive and negative voltage pins, as well as one or more communication and/or sensing pins useable to communicate with a battery management circuit included within such a battery pack, as described by example below. As such, an external device, such as the controller of an electronic lock, may determine a chemistry of the battery pack based on signals sensed at pins 113 (or, in some cases, based on the absence of such signals).

In some embodiments, as described herein, the pins 113 are used to sense the chemistry of the attached battery pack. In alternative embodiments, the interior assembly 108 includes a button 117 that is used to determine the chemistry of the attached battery pack. In an example, when a battery pack of a first chemistry is attached, the button 117 is pressed, and a signal is sent to the processing unit 116 to inform the processing unit 116 that the attached battery pack is of the first chemistry. In this example, when a battery pack with a second chemistry is attached, the battery pack may be shaped differently to not press the button 117, so the processing unit 116 does not receive the signal and infers that the attached battery pack has the second chemistry.

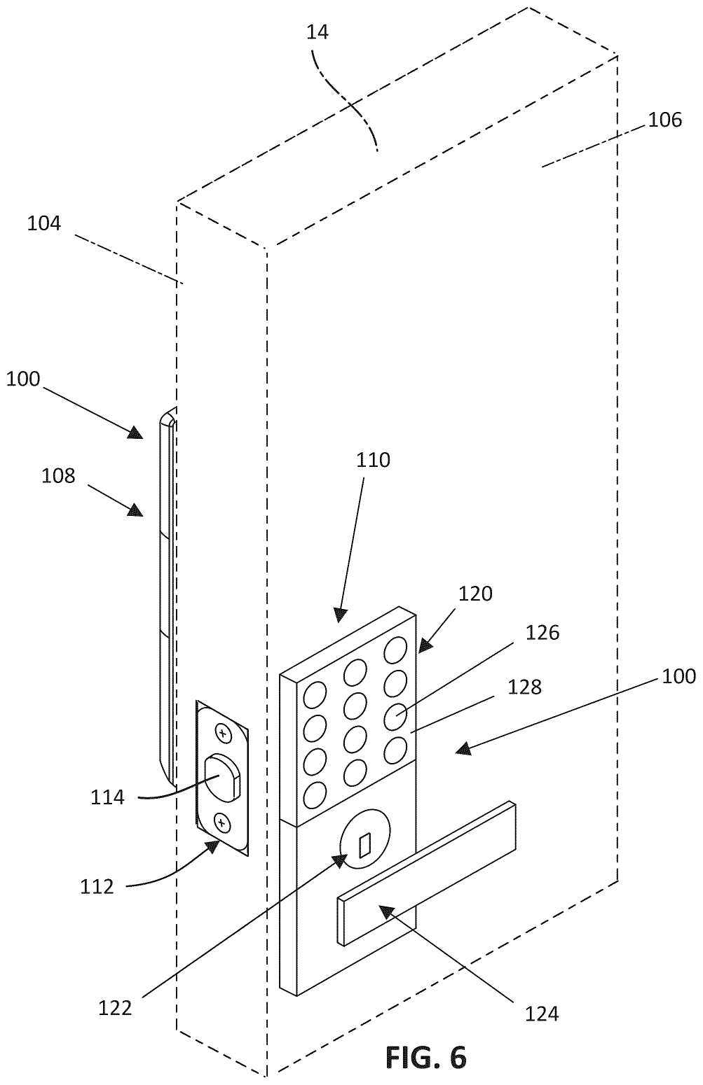

Referring to FIG. 6, the exterior assembly 110 can include exterior circuitry communicatively and electrically connected to the processing unit 116. For example, the exterior assembly 110 can include a keypad 120 for receiving a user input and/or a keyway 122 for receiving a key (not shown). The exterior side 106 of the door 14 can also include a handle 124. In some examples, the exterior assembly 110 includes the keypad 120 and not the keyway 122. In some examples, the exterior assembly 110 includes the keyway 122 and not the keypad 120. In some examples, the exterior assembly 110 includes the keyway 122 and the keypad 120. When a valid key is inserted into the keyway 122, the valid key can move the bolt 114 between the extended and retracted positions. When a user inputs a valid actuation passcode into the keypad 120, the bolt 114 may be moved between the extended and retracted positions. In some examples, the exterior assembly 110 is electrically connected to the interior assembly 108. Specifically, in some examples, the keypad 120 may be electrically connected to the interior assembly 108, specifically to the processing unit 116, by, for example, an electrical cable (not shown) that passes through the door 14. When the user inputs a valid actuation passcode via the keypad 120 that is recognized by the processing unit 116, an electrical motor is energized to retract the bolt 114 of latch assembly 112, thus permitting the door 14 to be opened from a closed position. Still further, an electrical connection between the exterior assembly 110 and the interior assembly 108 allows the processing unit 116 to communicate with other features included in the exterior assembly 110, as noted below. In some embodiments, however, one or more electrical components of the electronic lock 100 may not be active until a user interacts with the electronic lockset 100. As a result, battery power may be conserved until an electrical component or function is needed.

The keypad 120 can be any of a variety of different types of keypads. The keypad 120 can be one of a numeric keypad, an alpha keypad, and/or an alphanumeric keypad. The keypad 120 can have a plurality of characters displayed thereon. For example, the keypad 120 can include a plurality of buttons 126 that can be mechanically actuated by the user (e.g., physically pressed). In some examples, the keypad 120 includes a touch interface 128, such as a touch screen or a touch keypad, for receiving a user input. The touch interface 128 is configured to detect a user's “press of a button” by contact without the need for pressure or mechanical actuation. In some embodiments, interacting with the keypad 120 may cause an electrical component of the electronic lock 100 to be activated (e.g., may cause a switch to close), which may allow the user to actuate the bolt 114 using the keypad 120.

In alternative embodiments, one or more other types of user interface devices can be incorporated into the electronic lock 100. For example, in example implementations, the exterior assembly 110 can include a biometric interface (e.g., a fingerprint sensor, retina scanner, or camera including facial recognition), or an audio interface by which voice recognition could be used to actuate the lock 100. Still further, other touch interfaces may be implemented, e.g., where a single touch may be used to actuate the lock 100 rather than requiring entry of a specified actuation passcode.

FIG. 7 illustrate schematic representations of embodiments of the electronic lock 100 mounted to the door 14. Examples of the interior assembly 108, the exterior assembly 110, and the latch assembly 112 are shown. In other embodiments, the electronic lock 100 may include more or fewer components than those illustrated in connection with the FIG. 7. In some embodiments, the electronic lock 100 may include an electrical circuit that connects one or more components of the electronic lock 100 described herein. In examples, the electrical circuit may receive power from the battery 150 or from a different power source. In some embodiments, the electronic lock 100 may include a plurality of subcircuits, each of which may include one or more components of the electronic lock 100 described herein, and the subcircuits may, in some embodiments, allow the electronic lock 100 to selectively activate or deactivate only some electrical components.

The exterior assembly 110 is shown to include exterior circuitry 117, the keypad 120, and an exterior antenna 138 usable for communication with a remote device. In addition, the exterior assembly 110 can include one or more sensors 131, such as a camera, proximity sensor, button, or other mechanism by which conditions exterior to the door 14 can be sensed. In response to such sensed conditions, notifications may be sent by the electronic lock 100 to a server 18 or mobile device 200 including information associated with a sensed event (e.g., time and description of the sensed event, or remote feed of sensor data obtained via the sensor).

The exterior antenna 138 is capable of being used in conjunction with an interior antenna 142, such that the processing unit 116 can determine where a mobile device is located. In some embodiments, only a mobile device (e.g., the mobile device 200) that is paired with the electronic lock 100 and determined to be located on the exterior of the door 14 is able to actuate (unlock or lock) the door 14. This prevents unauthorized users from being located exterior to the door 14 of the electronic lock 100 and taking advantage of an authorized mobile device that may be located on the interior of the door 14, even though that authorized mobile device is not being used to actuate the door 14. In alternative arrangements, the electronic lock 100 is only actuatable from either the keypad 120 (via entry of a valid actuation passcode) or from an application installed on a mobile device.

As described above, the interior assembly 108 includes the processing unit 116. The interior assembly 108 can also include a motor 140, a motion sensor 143, and an interior antenna 142. As shown, the processing unit 116 includes at least one processor 144 communicatively connected to a security chip 145, a memory 146, various wireless network interfaces 147, 148, and a battery 150. For example, the processing unit 116 may include a network interface for communicating via the IEEE 802.11 standard (Wi-Fi®), the IEEE 802.15.4 standard (Zigbee®, Z-Wave®, and Thread), the IEEE 802.15.1 standard (Bluetooth®), or another standard. In some embodiments a Bluetooth interface 148 may be configured to communicate via a Bluetooth Low Energy (BLE) protocol. In some embodiments, the BLE interface 148 may be coupled with a security module 149. In some embodiments, a network interface for communicating via other communication protocols may be present, instead of, or in addition to, a Wi-Fi interface 147 and the BLE interface 148. For example, the electronic lockset 100 may include a network interface for communicating according to one or more of the following protocols: Thread, Matter, near-field communication (NFC), Z-Wave, ZigBee, Narrow Band IoT (NB-IoT), LoRa, 3G, LTE, 4G, 5G, or another protocol or network. The processing unit 116 is located within the interior assembly 108 and is capable of operating the electronic lock 100, e.g., by actuating the motor 140 to actuate the bolt 114.

In some examples, the processor 144 can process signals received from a variety of devices to determine whether the electronic lock 100 should be actuated. Such processing can be based on a set of preprogramed instructions (i.e., firmware) stored in the memory 146. In certain embodiments, the processing unit 116 can include a plurality of processors 144, including one or more general purpose or specific purpose instruction processors. In some examples, the processing unit 116 is configured to capture a keypad input event from a user and store the keypad input event in the memory 146. In other examples, the processor 144 receives a signal from the exterior antenna 138, the interior antenna 142, or a motion sensor 143 (e.g., a vibration sensor, gyroscope, accelerometer, motion/position sensor, or combination thereof) and can validate received signals in order to actuate the lock 100. In still other examples, the processor 144 receives signals from one or more network interfaces 147, 148 to determine whether to actuate the electronic lock 100.

In embodiments, the processor 144 determines a chemistry of the battery 150 and controls components of the electronic lock 100 based on the chemistry of the battery 150. In an example, the battery 150 is electrically connected to the processor 144 through one or more pins, and the processor 144 sends signals through at least one of the pins to determine the chemistry of the battery 150. In an embodiment, the electronic lock 100 includes five pins: a positive voltage pin, a negative voltage pin, a presence detection pin, and two communication pins (e.g., a data pin and a clock pin). A battery 150 of a first chemistry (e.g., lithium) may be part of a battery pack that includes five corresponding contacts while a battery 150 of a second chemistry (e.g., alkaline) may be part of a battery pack that includes two contacts (e.g., a positive voltage pin and a negative voltage pin). The processor 144 can determine the chemistry of the battery 150 by sending signals through one of the pins for which the battery of the second chemistry does not have a corresponding contact (e.g., the presence detect pin or one of the communication pins). If the processor 144 receives a response from the battery 150, the processor 144 can infer that the battery 150 has the first chemistry, and if the processor does not receive a response from the battery 150, the processor 144 can infer that the battery 150 has the second chemistry.

In other embodiments, the processor 144 may use a voltage of the battery 150 to determine the chemistry of the battery 150. In embodiments, when the battery 150 is a lithium battery, the battery 150 may have a voltage between approximately 6 volts and approximately 8.7 volts, and when the battery 150 is an alkaline battery, the battery 150 may have a voltage between approximately 5 volts and approximately 6.8 volts. When a sensed voltage on the battery 150 is below approximately 5 volts, the processor 144 can infer that the battery 150 is an alkaline battery. Similarly, when the sensed voltage on the battery 150 is above approximately 6.8 volts, the processor 144 can infer that the battery 150 is a lithium battery. In further embodiments, the processor 144 analyzes other values of the battery 150 to determine the chemistry of the battery 150, including a temperature of the battery 150 and an internal resistance of the battery 150.

In some embodiments, the processor 144 is connected with a button in the interior assembly (e.g., button 117 shown in FIG. 5) that sends signals to the processor 144 to indicate the chemistry of the battery 150; when the button is pressed, the processor 144 infers that the battery 150 has a first chemistry, and when the button is not pressed, the processor 144 infers that the battery 150 has a second chemistry. As described above, the battery 150 may be part of differently shaped battery packs depending on the chemistry of the battery 150, and the battery packs may interact differently with the button depending on the shape of the battery pack. In an example, when the battery 150 has a first chemistry (e.g., lithium), the battery 150 is included in a battery pack that is shaped to press the button when installed in the interior assembly 108. Similarly, when the battery 150 has a second chemistry (e.g., alkaline), the battery 150 is included in a battery pack that is shaped to not press the button when installed in the interior assembly 108.

In other embodiments, the processor 144 uses analog analysis to determine the chemistry of the battery 150. In an example, the processor 144 closes a circuit within the processing unit 116 to apply a load to the battery 150 and analyze a response of the battery 150 to determine the chemistry of the battery 150. For example, the processor 144 may measure a voltage across the load or a current through the load to determine the chemistry of the battery 150. In other examples, the processor 144 may measure other characteristics of the signal through the load to determine the chemistry of the battery 150.

Operation of the electronic lock 100 may vary depending on the chemistry of the battery 150. In embodiments, the electronic lock 100 operates in different operating modes based on the chemistry of the battery 150, and each operating mode may be associated with a battery chemistry—e.g., if the battery 150 has a first chemistry, the electronic lock 100 operates in a first operating mode, and if the battery 150 has a second chemistry, the electronic lock 100 operates in a second operating mode. The operating modes may be defined by settings stored in the memory 146 of the processing unit 116.

In an example, a process for determining a remaining power of the battery 150 may differ depending on a chemistry of the battery 150 determined by the processor 144. In embodiments, a battery 150 with a first chemistry (e.g., lithium) may be included in a battery pack that includes an integrated circuit that measures power into and out of the battery pack. The processor 144 can communicate with the battery pack (e.g., through pins, as described above) to receive data about the measured power into and out of the battery pack, and the processor 144 can use this data to estimate the remaining power of the battery 150. Alternatively, the chipset of the battery pack may use the data about the measured power into and out of the battery pack to estimate the remaining power of the battery 150 and communicate the estimate with the processor 144. A battery 150 with a second chemistry (e.g., alkaline) may be included in a battery pack that does not include a chipset for measuring the power into and out of the battery pack. To measure the remaining power of the battery 150 with the second chemistry, the battery 150 may be connected to a load with a known resistance, and the processor 144 may measure a current through the load to determine a voltage of the battery 150. In other embodiments, alternative processes may be used to measure the voltage of the battery 150 to estimate the remaining power of the battery 150.

In embodiments, operation of the motor 140 may differ depending on the chemistry of the battery 150 determined by the processor 144. In an example, the amount of power provided to the motor 140 by the processor 144 may be different for different battery chemistries—e.g., the motor 140 draws more power when the battery 150 is a lithium battery than when the battery 150 is an alkaline battery because the lithium battery can handle a higher load than the alkaline battery. In another example, pulse-width modulation of the motor 140 may vary based on the chemistry of the battery 150. Because a speed of the motor 140 is dependent on a voltage supplied to the motor 140 and different battery chemistries may supply different voltages, the processor 144 may change a width of the pulses and/or a frequency of the pulses based on the chemistry of the battery 150. Accordingly, a substantially similar voltage (alternatively, a similar amount of power at a slightly different voltage that varies based on battery chemistry) may be supplied to the motor 140 regardless of the chemistry of the battery 150. Additionally, a start-up process for the pulse-width modulation of the motor 140 may also change based on the chemistry of the battery 150. Because some battery chemistries can handle a load better (e.g., lithium batteries), the start-up process for the pulse-width modulation of the motor 140 may be eliminated depending on the chemistry of the battery 150.

In further embodiments, a low-power mode of the lock 100 may differ based on the chemistry of the battery 150. Because an estimate of the remaining power of the battery 150 may differ based on the chemistry of the battery 150, as described above, the estimate of remaining power may be less accurate if a less accurate process is used—e.g., the estimate may be less accurate if the remaining power of the battery 150 is estimated by measuring a voltage on the battery 150 than by measuring the power or energy that has flowed into and out of the battery 150. Accordingly, operation of the lock 100 during the low-power mode may differ based on the chemistry of the battery 150. In an example, when the battery 150 is an alkaline battery for which the remaining power is estimated by measuring the voltage of the battery 150, the lock may enter a low-power mode earlier than if the battery 150 is a lithium battery (with the remaining power estimated by measuring power into and out of the lithium battery) to account for potential inaccuracies in the estimate of the remaining power of the battery 150. Similarly, components of the lock 100 may be deactivated during the low-power mode when the battery 150 is an alkaline battery that are not deactivated during the low-power mode when the battery 150 is a lithium battery. For example, when in the low-power mode with an alkaline battery 150, the processor 144 may deactivate one or more wireless interfaces (e.g., a Wi-Fi interface 147) to conserve power, while such a wireless interface may remain active when a lithium battery is used (or may at least remain active for a longer period). Other examples of methods of mitigating battery use are described in U.S. patent application Ser. No. 18/806,129, entitled “ELECTRONIC LOCK WITH BATTERY USE MITIGATION”, filed Aug. 15, 2024, the disclosure of which is incorporated by reference in its entirety.

In some embodiments, the processing unit 116 includes a security chip 145 that is communicatively interconnected with one or more instances of processor 144. The security chip 145 can, for example, generate and store cryptographic information usable to generate a certificate usable to validate the electronic lock 100 with a remote system, such as a server or a mobile device (e.g., the server 18 or the mobile device 200). In certain embodiments, the security chip 145 includes a one-time write function in which a portion of memory of the security chip 145 can be written only once, and then locked. Such memory can be used, for example, to store cryptographic information derived from characteristics of the electronic lock 100, or its communication channels with the server 18 or one or more mobile devices 200. Accordingly, once written, such cryptographic information can be used in a certificate generation process which ensures that, if any of the characteristics reflected in the cryptographic information are changed, the certificate that is generated by the security chip 145 would become invalid, and thereby render the electronic lock 100 unable to perform various functions, such as communicate with the server 18 or the mobile device 200, or operate at all, in some cases.

In some embodiments, the security chip 145 may be configured to generate a pairing passcode that, when entered using the keypad 120 of the electronic lock 100, triggers a pairing mode of one or more of the network interfaces of the electronic lock 100 that enables the electronic lock 100 to pair with a proximate mobile device. In some embodiments, a pairing passcode may be used to pair with a proximate mobile device. In some examples, the pairing passcode is provided to a user upon initial setup/activation of the electronic lock 100 (e.g., via an electronic lock application associated with the electronic lock 100 operating on the mobile device 200). In some examples, the pairing passcode is a random value. In some examples, the user may be enabled to change the pairing passcode by setting their own code or by requesting a random value to be generated by the electronic lock application operating on the mobile device 200. In some examples, the length of the pairing passcode is variable. According to an aspect, for increased security, the pairing passcode may be a limited-use passcode. For example, the pairing passcode may be limited to a single use or may be active for a preset or administrative user-selected time duration. In further examples, a digit of the pairing passcode may correspond to a setting that may instruct the electronic lock 100 to perform one or more of: disable the pairing passcode after it has been used; keep the pairing passcode enabled after it has been used; or reset the pairing passcode to a new random value after it has been used.

The memory 146 can include any of a variety of memory devices, such as using various types of computer-readable or computer storage media. A computer storage medium or computer-readable medium may be any medium that can store a program or instructions for performing one or more operations, steps, or methods described herein. By way of example, computer storage media may include dynamic random access memory (DRAM) or variants thereof, solid state memory, read-only memory (ROM), electrically erasable programmable ROM, and other types of devices and/or articles of manufacture that store data. Computer storage media generally includes at least one or more tangible media or devices. Computer storage media can, in some examples, include embodiments including entirely non-transitory components. In some embodiments, the processor 144 may execute programs or instructions stored by the memory 146. In some embodiments, the memory 146 may store one or more codes that may be input by a user to actuate the bolt 114. For instance, a user may input a code into the keypad 120, or the mobile device 200 may provide a code to the electronic lock 100 via a network interface. To validate the code, the processor 144 may compare the input code to the one or more codes stored in the memory 146.

As noted above, the processing unit 116 can include one or more wireless interfaces, such as Wi-Fi interface 147, a Bluetooth interface 148, and/or another interface. Other RF circuits can be included as well. In the example shown, the interfaces 147, 148 are capable of communication using at least one wireless communication protocol. In some examples, the processing unit 116 can communicate with a remote device, such as the server 18, via a first network interface (e.g., the Wi-Fi interface 147) and with a proximate device, such as the mobile device 200, via a second network interface (e.g., the interface 148). In some embodiments, the processing unit 116 is configured to communicate with the mobile device 200 via a short-range wireless interface, such as a network interface configured to communicate using a protocol for any one or more of BLE, NFC, Thread, or another protocol. When the mobile device 200 is out of range of such network, the mobile device 200 may communicate with the server 18, which may relay communications to the electronic lock 100. In some embodiments, the electronic lock 100 may use the Wi-Fi interface 147 to communicate with the server 18. In other embodiments, the electronic lock 100 may communicate with a hub device or router device using a different network protocol (e.g., BLE, NFC, Thread), and the hub device or router may route communications between the server 18 and the electronic lock 100.

In some embodiments, the BLE interface 148 is an example of a low-power network interface. Other examples of low-power network interfaces many include an interface for communicating via a near-field communication (NFC) protocol, a Thread protocol, a Z-Wave protocol, a ZigBee protocol, a Narrow Band IoT (NB-IoT) protocol, a LoRa protocol, or another protocol. In some embodiments, a low-power network interface may be a network interface that itself is not coupled to a power source, such as a passive NFC reader or other reader device. In some embodiments, a low-power network interface may be an interface that consumes less power than the Wi-Fi interface 147 for performing a similar task over a similar amount of time as a Wi-Fi interface 147.

In some embodiments, the Wi-Fi interface 147 is an example of a high-power network interface. Other examples of high-power network interfaces in the electronic lock 100 may include an interface for communicating via one or more of 3G, LTE, 4G, or 5G. In some embodiments, the electronic lock 100 may prioritize communicating with a mobile device via a low-power network interface over a high-power network interface. For instance, if the mobile device 200 is coupled to the electronic lock 100 via a high-power network interface and a low-power network interface, then the electronic lock 100 may be configured to communicate with the mobile device 200 via the low-power network interface. Examples of methods of prioritizing a particular wireless interface and/or protocol are described in U.S. patent application Ser. No. 18/806,175, entitled “ELECTRONIC LOCKSET HAVING MULTIPLE WIRELESS RADIOS”, filed Aug. 15, 2024, the disclosure of which is incorporated by reference in its entirety. In some embodiments, the electronic lock 100 may disable the high-power network interface, as is further described below. Additionally, in some embodiments, the electronic lock 100 may deactivate one or more of the network interfaces to save battery power or in response to determining that the network interface may not be needed.

The interior assembly 108 also includes the battery 150 to power the electronic lock 100. In some embodiments, the electronic lock 100 may include a plurality of batteries, or the electronic lock 100 may also include other power sources. As described above, the electronic lock 100 is compatible with batteries of different chemistries. In one example, the battery 150 may be a standard single-use (disposable) alkaline battery. Alternatively, the battery 150 may be rechargeable lithium battery. As described above, operation of the electronic lock 100 may differ based on the chemistry of the battery 150.

In some embodiments, the electronic lock 100 may include, or be coupled with, a battery charging system, such as a solar panel. The battery charging system may be used when the chemistry of the battery 150 allows the battery 150 to be rechargeable (e.g., if the battery 150 is a lithium battery). In an example, a solar panel may be positioned within the exterior assembly 110, but persistently electrically connected to other circuitry of a battery charging system such that the battery 150 may be recharged even when other components may be disconnected. In other embodiments, aspects of the battery charging system may be included within the exterior assembly 110 as well.

In some embodiments, the battery charging system may include a signal harvesting device, such as a device for harvesting radio waves used for communicating over Wi-Fi or 5G. In such embodiments, these radio waves may be harvested and used to charge the battery 150. Examples methods of harvesting are described in U.S. Pat. No. 9,328,532, entitled “ELECTRONIC LOCKSET WITH MULTI-SOURCE ENERGY HARVESTING CIRCUIT”, the disclosure of which is hereby incorporated by reference in its entirety.

The interior assembly 108 also includes the motor 140 that is capable of actuating the bolt 114. In use, the motor 140 receives an actuation command from the processing unit 116, which causes the motor 140 to actuate the bolt 114 from the locked position to the unlocked position or from the unlocked position to the locked position. In some examples, the motor 140 actuates the bolt 114 to an opposing state. In some examples, the motor 140 receives a specified lock or unlock command, where the motor 140 only actuates the bolt 114 if the bolt 114 is in the correct position. For example, if the door 14 is locked and the motor 140 receives a lock command, then no action is taken. If the door 14 is locked and the motor 140 receives an unlock command, then the motor 140 actuates the bolt 114 to unlock the door 14. In some embodiments, a mechanism other than the motor 140 may be used to electrically actuate the bolt 114, such as magnets or solenoids. As described above, the motor 140 may draw different amounts of power depending on the chemistry of the battery 150. For example, if the battery 150 is a lithium battery, the motor 140 may draw more power than if the battery 150 is an alkaline battery.

As noted above, the interior antenna 142 may also be located in the interior assembly 108. In some examples, the interior antenna 142 may operate with the exterior antenna 138 to determine the location of a mobile device. In some examples, only a mobile device determined to be located on the exterior side 106 of the door 14 is able to unlock (or lock) the door 14. This prevents unauthorized users from being located near the electronic lock 100 and taking advantage of an authorized mobile device that may be located on the interior side 104 of the door 14, even though the authorized mobile device is not being used to unlock the door 14. In alternative embodiments, the interior antenna 142 can be excluded entirely, since the electronic lock 100 is actuated only by an authorized mobile device.

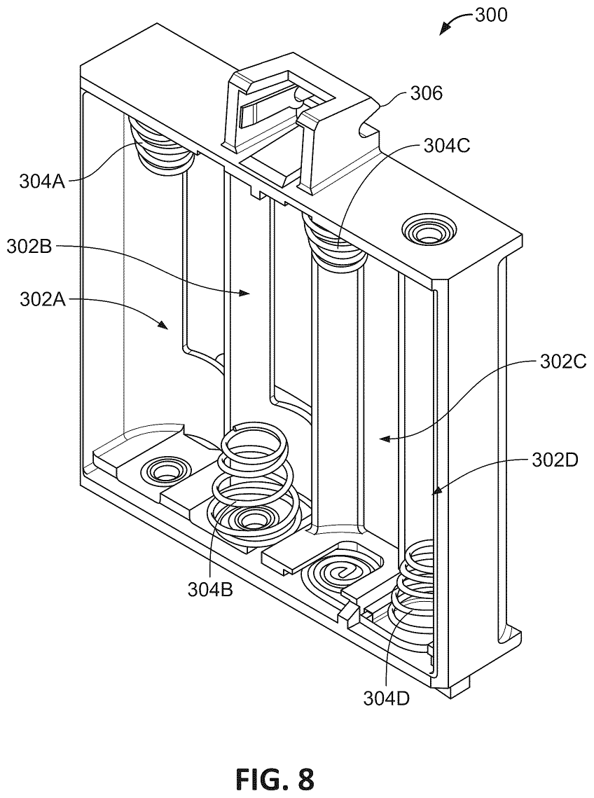

In the example of FIG. 8, one or more of the network interfaces 147, 148 may not be present. For example, in some embodiments, the electronic lock 100 may not have wireless communication capabilities, or the electronic lock 100 may only have an interface for communicating via either a low-power network interface or a high-power network interface. Additionally, in some embodiments, the electronic lock 100 may selectively activate and deactivate one or more of the network interfaces 147, 148. For instance, the electronic lock 100 may deactivate a high-power network interface while keeping a low-power network interface active, or vice-versa.

In some embodiments, the electronic lock 100 is made of mixed metals and plastic, with engineered cavities to contain electronics and antennas. For example, in some embodiments, the lock 100 utilizes an antenna near the exterior face of the lockset 100, designed inside the metal body of the lockset 100 itself. The metal body can be engineered to meet strict physical security requirements and also allow an embedded front-facing antenna to propagate RF energy efficiently.

In still further example embodiments, the electronic lock 100 can include an integrated motion sensor 143. Using such a motion sensor (e.g., an accelerometer, gyroscope, or other position or motion sensor) and wireless capabilities of a mobile device or an electronic device (i.e., fob) with these capabilities embedded inside can assist in determining additional types of events (e.g., a door opening or door closing event, a lock actuation or lock position event, or a knock event based on vibration of the door). In some cases, motion events can cause the electronic lock 100 to perform certain processing, e.g., to communicatively connect to or transmit data to the mobile device 200 or the server 18 or to activate or deactivate an electrical component of the electronic lock 100.

In some embodiments, other lock actuation sequences may not require use of a motion sensor 143. For example, if a mobile device is in valid range of the electronic lock 100 when using a particular wireless protocol, then a connection will be established with the electronic lock 100. Other arrangements are possible as well, using other connection sequences and/or communication protocols.

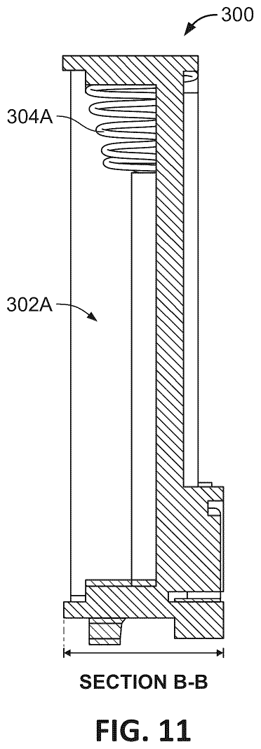

Turning to FIGS. 8-11, an example embodiment of a battery pack 300 for batteries of a first chemistry is shown. For example, the batteries may be alkaline batteries. In the illustrated embodiment, the battery pack 300 includes four battery holders 302 for removably attaching four batteries (not shown) to the battery pack 300. In alternative embodiments, the battery pack 300 may include different number of battery holders 302 for holding different numbers of batteries. In an example, changing the number of batteries in the battery pack 300 changes a voltage supplied by the battery pack 300.

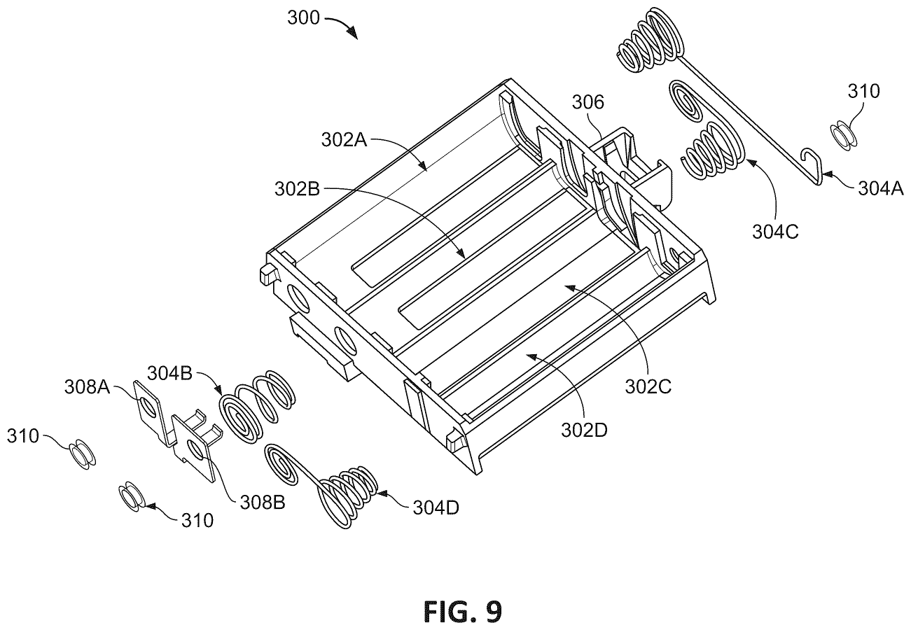

Batteries are held in the battery holders 302 using springs 304. The springs 304 apply pressure against attached batteries to hold the batteries in the battery pack 300. Additionally, the springs electrically connect attached batteries in series (best shown in FIG. 9). In the illustrated embodiment, a first spring 304A electrically connects a negative terminal of a battery in a first battery holder 302A to a positive terminal of a battery in a fourth battery holder 302D. A fourth spring 304D electrically connects a negative terminal of the battery in the fourth battery holder 302D to a positive terminal of a battery in a third battery holder 302C. A third spring 304C electrically connects a negative terminal of the battery in the third battery holder 302C to a positive terminal of a battery in a second battery holder 302B. A second spring 304B is electrically connected to a negative terminal of the battery in the second battery holder 302B. In alternative embodiments, different attachment mechanisms are used to removably attach batteries to battery pack 300. Additionally, in alternative embodiments, batteries in the battery holders 302 may be connected in parallel, rather than in series.

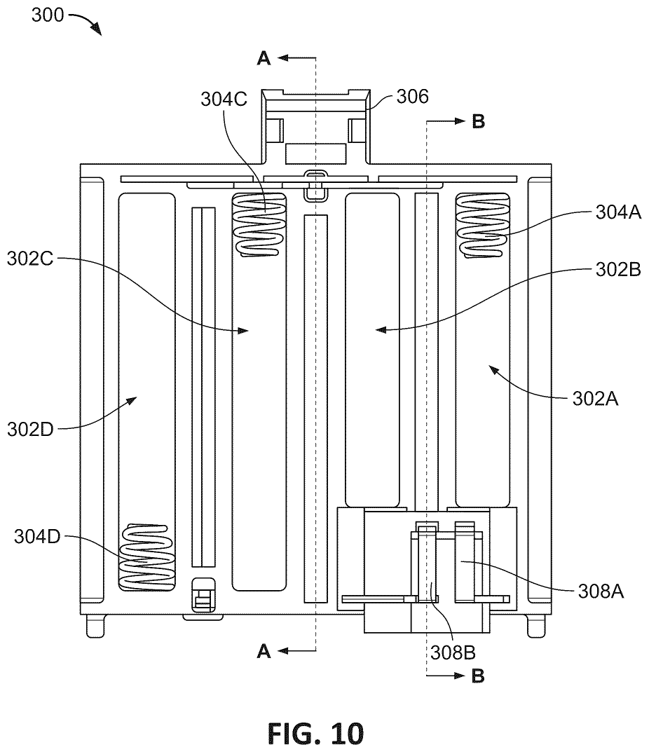

The battery pack 300 includes one or more contacts 308 (best shown in FIGS. 9 and 10) that connect to pins in an electronic lock to electrically connect the battery pack 300 to the electronic lock, as described above. In the illustrated embodiment, the battery pack 300 includes two contacts 308. In alternative embodiment, the battery pack 300 includes a different number of contacts 308. A first contact 308A is electrically connected to a positive terminal of the battery in the first holder 302A, and a second contact 308B is electrically connected to the negative terminal of the battery in the second holder 302B. Because each of the batteries held in the battery holders 302 are electrically connected in series by the springs 304, the contacts 308 act as a positive voltage contact and a negative voltage contact for the battery pack 300. As described above, the contacts 308 may be used by the electronic lock to determine a chemistry of the batteries held in the battery pack 300.

In the illustrated embodiment, the contacts 308 and one or more of the springs 304 are attached to the battery pack 300 using rivets 310. In alternative embodiments, different mechanical fasteners may be used to attach the contacts 308 and springs 304 to the battery pack 300.

The battery pack 300 also includes a connector 306 that couples with a latch on an electronic lock (such as latch 115, shown in FIG. 5) to removably attach the battery pack 300 to the electronic lock. In alternative embodiments, different connectors 306 are used to connect the battery pack to the electronic lock, including other mechanical fasteners.

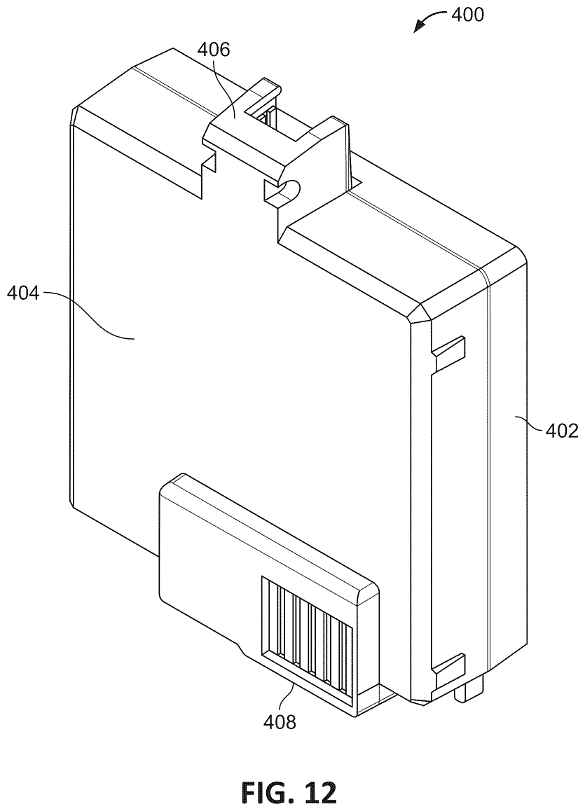

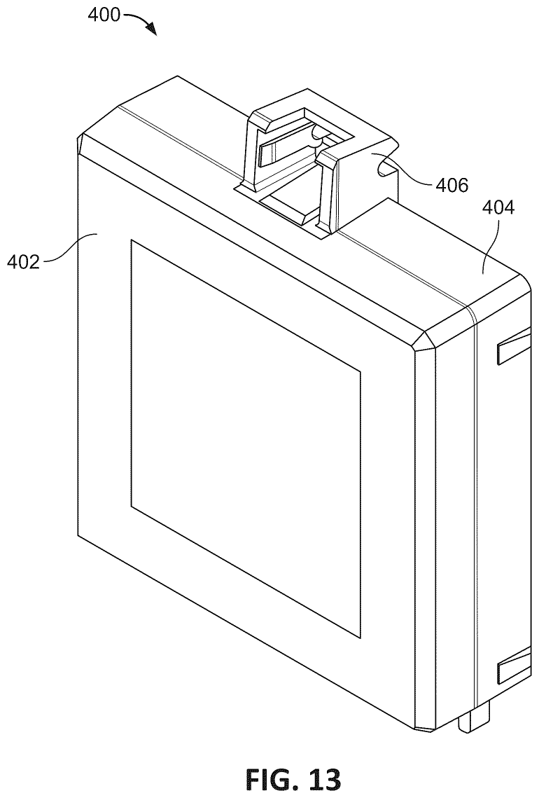

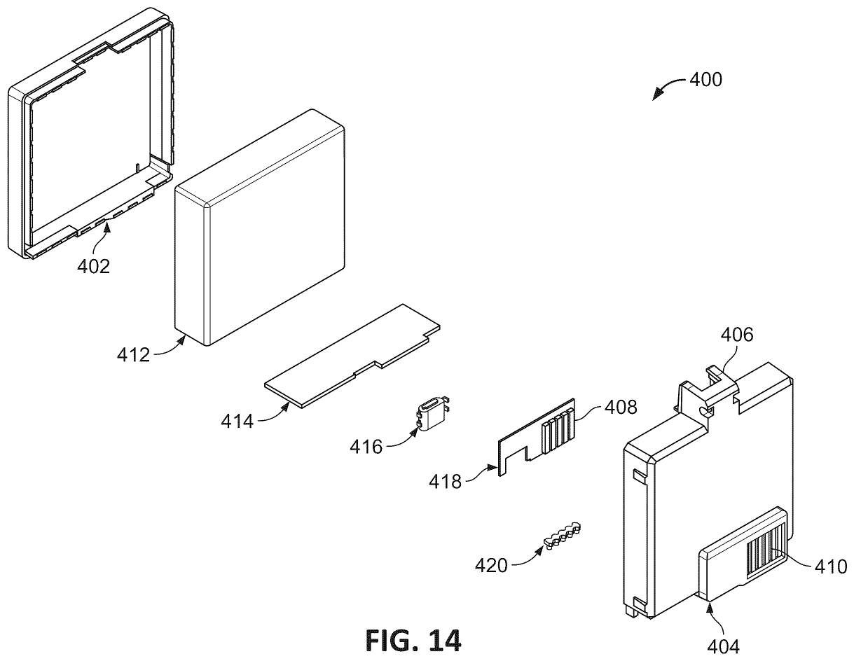

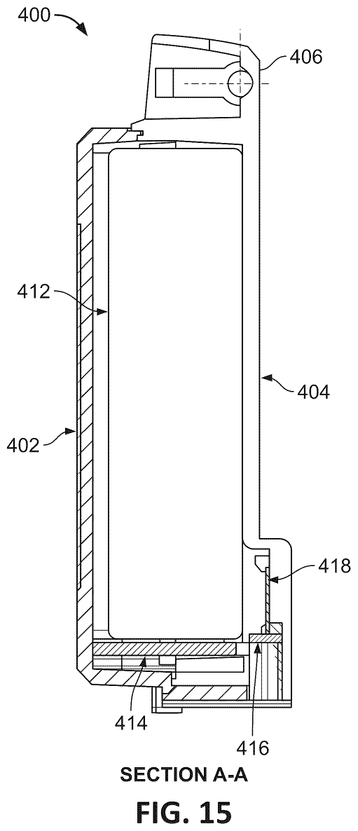

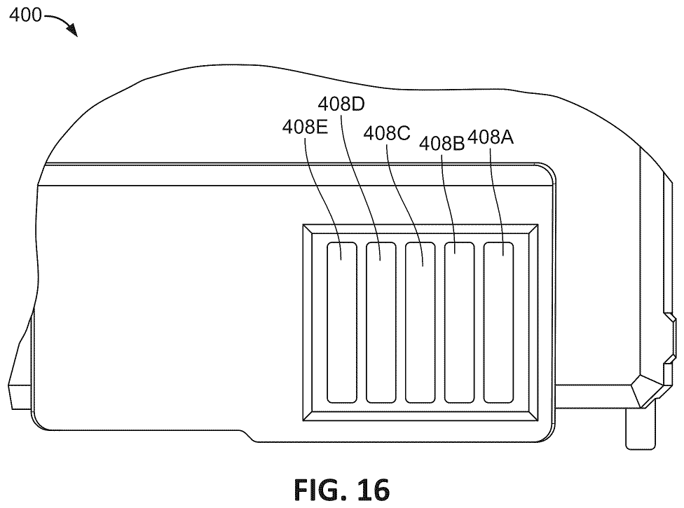

FIGS. 12-17 illustrate an example embodiment of a battery pack 400 for batteries of a second chemistry. For example, the battery pack 400 may be used for lithium batteries. In the illustrated embodiment, the battery pack 400 includes a back cover 402 and a front cover 404 that connect with one another to house a battery 412 (best shown in FIGS. 14 and 15). Like the battery pack 300 shown in FIGS. 8-11, the battery pack 400 includes a connector 406 to removably attach the battery pack 400 to an electronic lock.

The battery pack 400 includes, in the example shown, five contacts 408 that connect to pins in the electronic lock to electrically connect the battery pack 400 to the electronic lock, as described above. In an example, a first contact 408A is a positive voltage contact, a second contact 408B is a presence detection contact, a third contact 408C is a negative voltage contact, a fourth contact 408D is a communication contact (e.g., a data contact), and a fifth contact 408E is another communication contact (e.g., a clock contact). As described above, the contacts 408 may be used by the electronic lock to determine a chemistry of the battery 412 housed in the battery pack 400. In alternative embodiments, the battery pack 400 may include pins which connect to contacts in the electronic lock.

In embodiments, the battery pack 400 includes one or more circuits. Examples of circuits included in the battery pack 400 include printed circuit boards (PCBs) and integrated circuits (best shown in FIG. 14). In the illustrated embodiment, the battery pack 400 includes three circuits 414-418: two PCBs 414, 418 and an integrated circuit 416. In the illustrated embodiment, the PCB 418 includes the contacts 408, and the contacts 408 are exposed to pins in the electronic lock through openings 410 in the front cover 404 of the battery pack 400.

The circuits 414-418 of the battery pack 400 may control operations of the battery pack 400. For example, at least one of the circuits 414-418 measures voltage and/or current into and out of the battery pack 400. As described above, this data may be used to estimate a remaining power of the battery 412 in the battery pack 400. In embodiments, the circuits 414-418 use signals received through the contacts 408 to change operation of the battery pack 400. For example, if a signal is not received at a presence detect contact 408B, the battery pack 400 may determine that it is not connected at an electronic lock, and to conserve power of the battery 412, operations of the battery pack 400 may be suspended—e.g., the battery pack 400 may not measure power into and out of the battery pack 400 while the battery pack 400 is not connected to an electronic lock.

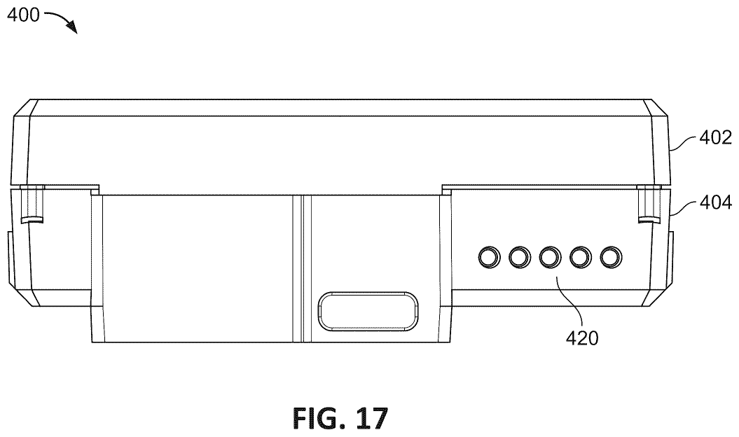

In embodiments, the battery pack 400 includes one or more visual indicators 420 (best shown in FIGS. 14 and 17) that indicate a remaining power of the battery 412. In an example, the visual indicators 420 are a plurality of LEDs, and the number of LEDs that are illuminated correspond to the remaining power of the battery 412—e.g., if four out of five LEDs are illuminated, the battery 412 has approximately 80% of its maximum power remaining.

Additionally, while the illustrated embodiment shows a single battery 412, in alternative embodiments, one or more additional batteries may be included. For example, the battery 412 may include multiple batteries connected in series and/or in parallel. Including multiple batteries may change a voltage of the battery pack 400 and/or an overall output voltage.

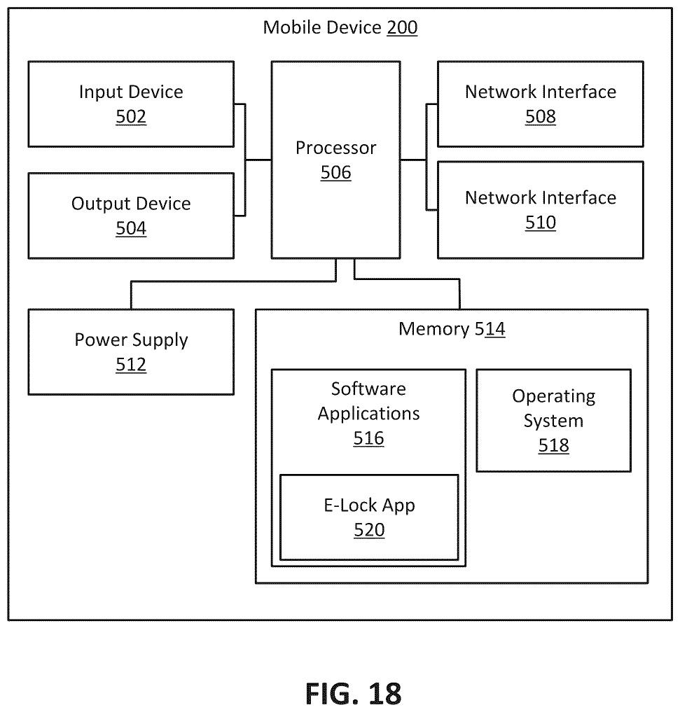

FIG. 18 illustrates a schematic diagram of a mobile device, such as the mobile device 200, usable in embodiments of the present disclosure. In some embodiments, the mobile device 200 operates to form a connection with a network enabled security device such as the electronic lock 100. In some embodiments, the mobile device 200 may communicate with the server 18 via a Wi-Fi or mobile data connection. Thus, in some embodiments, the mobile device 200 can operate to communicate information between a, electronic lock and a server (e.g., the electronic lock 100 and the server 18). The mobile device 200 shown in FIG. 18 includes an input device 502, an output device 504, a processor 506, a first network interface 508, a second network interface 510, a power supply 512, and a memory 514. In some embodiments, the first network interface 508 may be a Wi-Fi interface, and the second network interface 510 may be a Bluetooth interface. In some embodiments, the mobile device 200 may include an interface to communicate via a cellular network, a Thread protocol, near-field communication protocol, or another protocol or network type.

The input device 502 operates to receive input from external sources. Such sources can include inputs received from a user (e.g., the user 12). The inputs can be received through a touchscreen, a stylus, or a keyboard. In some embodiments, the input device may receive a voice input.

The output device 504 operates to provide output of information from the mobile device 200. For example, a display can output visual information while a speaker can output audio information.

The processor 506 reads data and instructions. The data and instructions can be stored locally, received from an external source, or accessed from removable media. In some examples, the first network interface 508 is similar to the Wi-Fi interface 147. In some embodiments, a Wi-Fi connection may be established between the mobile device 200 and the server 18. In some embodiments, a connection via a cellular network may be established between the mobile device 500 and the server 18. In some embodiments, the second network interface 510 is similar to the Bluetooth interface 148. In some examples, a Bluetooth connection may be established between the mobile device 200 and the electronic lock 100. In some embodiments, a connection according to an NFC protocol, Thread protocol, or other protocol may be established between the mobile device 200 and the electronic lock 100.

The power supply 512 provides power to the processor 506. The memory 514 includes software applications 516 and an operating system 518. The memory 514 contains data and instructions that are usable by the processor to implement various functions of the mobile device 200.

The software applications 516 can include applications usable to perform various functions on the mobile device 200. One such application is an electronic lock application 520. In some embodiments, the electronic lock application 520 may be used to interact with the electronic lock 100. In some embodiments, the electronic lock application 520 may be used to interact with the server 18. In other embodiments, the mobile device 200 may include more or fewer components than those illustrated in the example of FIG. 18.

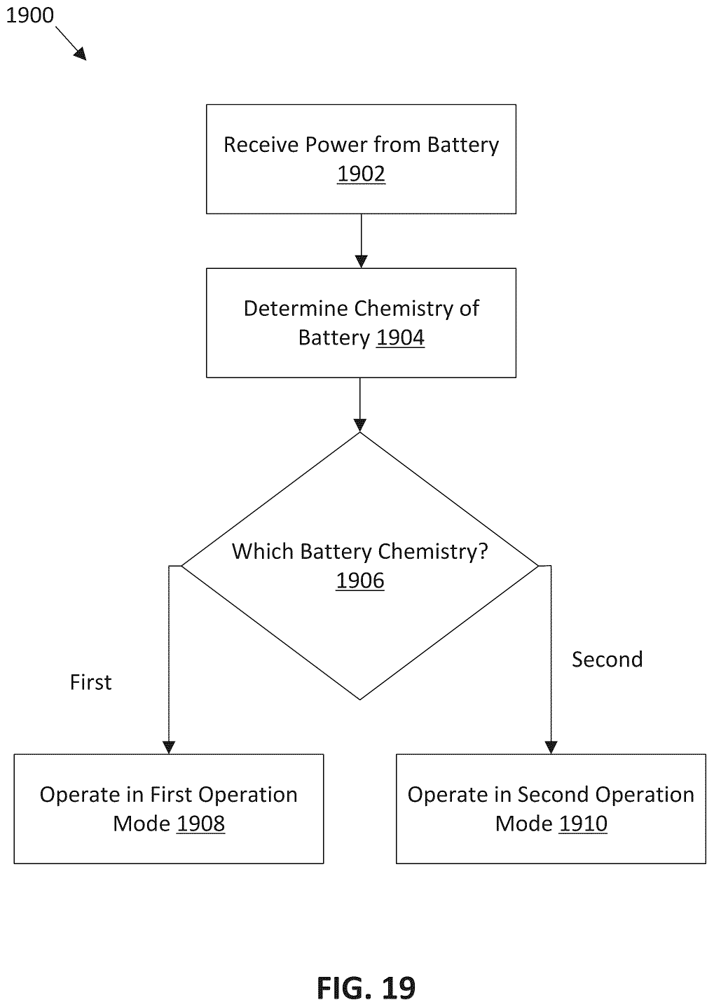

FIG. 19 illustrates a flowchart of an example method 1900 for operating an electronic lock based on a chemistry of an attached battery pack. The method 1900 includes operations 1902, 1904, 1906, 1908, 1910. In embodiments, the operations 1902-1910 may be performed by a processing unit of the electronic lock.

The operation 1902 includes receiving power at an electronic lock from an attached battery pack. In an embodiment, the battery pack includes contacts that electrically connect the battery pack to pins on the electrical lock, and power flows from contacts of the battery pack to the pins of the electronic lock to power the electronic lock. In alternative embodiments, the battery pack includes pins which electrically connect to contacts in the electronic lock.

The operation 1904 includes determining a chemistry of the battery pack. As described above, there are multiple methods for determining the chemistry of the battery pack. In an example, communication with the battery pack is used to determine the chemistry of the battery pack—e.g., a processor of the electronic lock transmits a signal to the battery pack, and the chemistry of the battery pack is determined based on whether the battery pack responds to the signal. In another example, a voltage of the battery pack is measured and compared against one or more thresholds to determine the chemistry of the battery pack. In embodiments, any of the methods for determining battery chemistry may be used. In some embodiments, multiple methods may be used to determine the chemistry of the battery pack. In an example, a processing unit of the electronic lock determines the chemistry of the battery pack.

The operation 1906 includes selecting an operation mode based on the chemistry of the battery pack. In the illustrated method 1900, the operation 1906 includes selecting from two operation modes based on the battery having a first chemistry or a second chemistry. If the battery chemistry is a first chemistry (e.g., lithium), the lock operates in a first operation mode (operation 1908). If the battery chemistry is a second chemistry (e.g., alkaline), the lock operates in a second operation mode (operation 1910). The operation modes may be configured based on settings stored in a memory of the electronic lock.

In alternative embodiments, the operation 1906 may include selecting from three or more operation modes based on three or more battery chemistries. Similarly, in the illustrated embodiment, each operation mode is associated with a single battery chemistry—i.e., the first operation mode is associated with the first chemistry, and the second operation mode, which is different from the first operation mode, is associated with the second chemistry. In alternative embodiments, each operation mode is associated with one or more battery chemistries—i.e., an operation mode may be associated with two or more battery chemistries.

In embodiments, the operation modes are based on settings stored within a memory of the electronic lock. Similarly, associations between operation modes and battery chemistries are stored in the memory of the electronic lock, in some embodiments.

As described above, various aspects of electronic lock may change based on the chemistry of the battery pack and the selected operation mode. For example, operation of a motor of the electronic lock may vary based on the chemistry of the battery pack—e.g., the power drawn by the motor may depend on the chemistry of the battery pack. For example, a battery chemistry that may be indicative of a higher capacity battery (e.g., lithium) may be associated with an operation mode that allows for greater power draw by the motor as compared to a battery chemistry that is indicative of a lower capacity battery (e.g., alkaline). Accordingly, when a higher capacity battery is present, a greater torque resistance may be overcome by the electronic lock (e.g., due to door misalignment, and the like). In another example, a process for determining the remaining power of the battery pack depends on the chemistry of the battery pack.

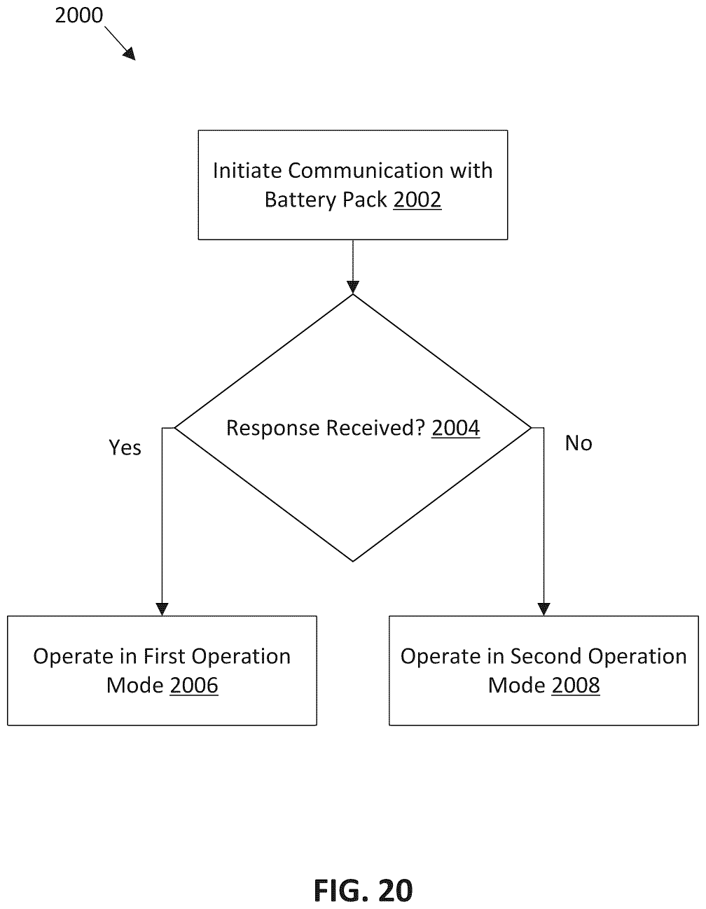

FIG. 20 illustrates a flowchart of an example method 2000 for determining a chemistry of a battery pack. The method 2000 includes operations 2002, 2004, 2006, 2008. In embodiments, the operations 2002-2008 may be performed by a processing unit of an electronic lock.

The operation 2002 includes initiating communication with a battery pack attached to an electronic lock. In an example, a signal is transmitted to the battery pack. In an embodiment, the signal is sent by a processing unit of the electronic lock through one or more pins of the electronic lock. Depending on the chemistry of the battery pack, the battery pack may or may not have a corresponding one or more contacts electrically connected to the one or more pins of the electronic lock. If the battery pack has a corresponding one or more contacts, the battery pack receives the signal from the electronic lock. If the battery pack does not have a corresponding one or more contacts, the battery pack may not receive the signal from the electronic lock.

In an example, as described above, the electronic lock has five pins: a positive voltage pin, a negative voltage pin, two communication pins, and a presence detect pin. A first battery pack for a battery of a first chemistry (shown in FIGS. 12-17) includes five contacts: a positive voltage contact, a negative voltage contact, two communication contacts, and a presence detect contact. A second battery pack for a battery of a second chemistry (shown in FIGS. 8-11) includes two contacts: a positive voltage contact and a negative voltage contact. In this example, the electronic lock may send a signal to the battery pack through one or both of the communication pins and/or the presence detect pin. If the first battery pack were attached to the electronic lock, the first battery pack would receive the signal because the first battery pack has corresponding contacts for the communication pins and the presence detect pin. If the second battery pack were attached to the electronic lock, because the second battery pack does not have contacts corresponding to the communication pins or the presence detect pin of the electronic lock, the second battery pack would not receive the signal from the electronic.

The operation 2004 includes determining if a response is received from the battery pack. In an example, the response is a signal sent from a circuit of the battery pack to the processor of the electronic lock. In an embodiment, because some battery packs do not have a contact corresponding to the pin through which the signal is transmitted from the electronic lock in the operation 2002, those battery packs do not receive the signal from the electronic lock and therefore do not respond. The battery packs that have a contact corresponding to the pin through which the signal is transmitted from the electronic lock receive the signal and may respond.

A chemistry of the battery pack is determined based on whether a response is received, and an appropriate operation mode is selected based on the chemistry of the battery pack. If a response is received during the operation 2004, the electronic lock may determine that the attached battery pack has a first chemistry. Accordingly, the electronic lock may operate in a first operation mode (operation 2006). Conversely, if a response is not received during the operation 2004, the electronic lock may determine that the attached battery pack has a second chemistry and operate in a second operation mode (operation 2008). In an embodiment, a processing unit of the electronic lock determines the chemistry of the battery pack based on the response and initiates operation in a selected operation mode. The operation modes may be configured based on settings stored in a memory of the electronic lock.

Continuing the example described above with respect to the operation 2002, if the first battery pack were attached to the electronic lock, the first battery pack wound receive the signal and, accordingly, would respond. Based on the response, the electronic lock may determine that the attached battery pack has a first chemistry and select an appropriate operation mode in which to operate. If the second battery pack were attached, the second battery pack wound not receive the signal and, accordingly, would not respond. Because the electronic lock does not receive a response, the electronic lock may determine that the attached battery pack has a second chemistry and select an appropriate operation mode in which to operate.

While the illustrated method 2000 shows selecting between two operation modes based on whether a response is received or not, in alternative embodiments, three or more operation modes may be selected based on the response—or lack thereof. For example, the electronic lock may select from multiple operation modes based on the type of response received in addition to an operation mode for if no response is received—e.g., if the response is a signal with a first frequency, the electronic lock may determine that the battery pack has a first chemistry and select a first operation mode, whereas if the response is a signal with a second frequency, the electronic lock may determine that the battery pack has a second chemistry and select a second operation mode; if no response is received, the electronic lock may determine that the battery pack has a third chemistry and select a third operation mode.

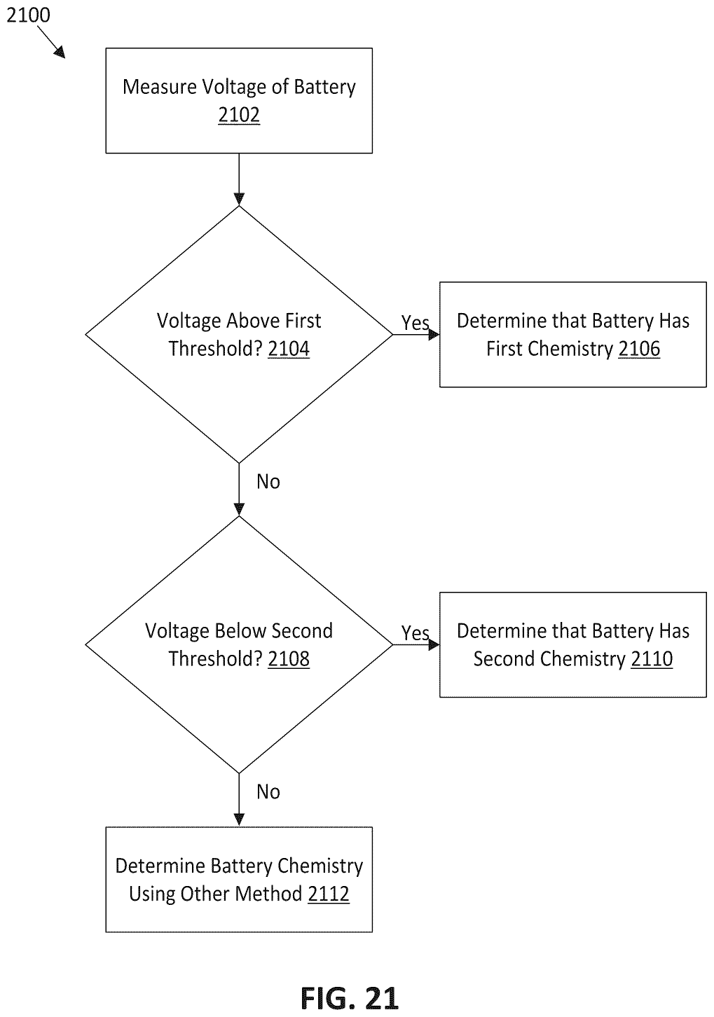

FIG. 21 illustrates a flowchart of a second example method 2100 for determining a chemistry of a battery pack. The method 2100 includes operations 2102, 2104, 2106, 2108, 2110, 2112. In embodiments, the operations 2102-2112 may be performed by a processing unit of an electronic lock.

The operation 2102 includes measuring a voltage of the battery pack. In an example, the voltage of the battery pack may be measured by connecting the battery pack to a load with a known resistance and measuring a current through the load to calculate the voltage of the battery pack.

The operation 2104 includes comparing the measured voltage to a first threshold. The first threshold may be based on voltage ranges of potential battery chemistries. In an example, the method 2100 may be performed to determine whether the battery pack has a lithium chemistry or an alkaline chemistry. In this example, a lithium battery pack may have a voltage between approximately 6 volts and approximately 8.7 volts, and an alkaline battery pack may have a voltage between approximately 5 volts and approximately 6.8 volts. Accordingly, the first threshold may be approximately 6.8 volts, as a measured voltage above approximately 6.8 volts would be in the range of the lithium battery pack and outside of the range of the alkaline battery pack.

If the measured voltage is above the first threshold, the method 2100 advances to the operation 2106, and the battery pack is determined to have a first chemistry (e.g., lithium). As described above, an electronic lock that determines that the battery pack has a first chemistry may operate in a corresponding operation mode and control aspects of the operation of the electronic lock accordingly, such as operation of a motor.

If the measured voltage is not above the first threshold, the method 2100 advances to the operation 2108, which includes comparing the measured voltage to a second threshold. Continuing the example described above, the second threshold may be approximately 6 volts, as a measured voltage below approximately 6 volts would be in the range of the alkaline battery pack and outside of the range of the lithium battery pack.

If the measured voltage is below the second threshold, the method 2100 advances to the operation 2110, and the battery pack is determined to have a second chemistry (e.g., alkaline). As described above, an electronic lock that determines that the battery pack has a second chemistry may operate in a corresponding operation mode and control aspects of the operation of the electronic lock accordingly.

If the measured voltage is not below the second threshold, the method 2100 advances to the operation 2112, which includes using an alternative method to determine the chemistry of the battery pack. Any of the methods described above may be used to determine the chemistry of the battery pack, including attempting communication with the battery pack or measuring other characteristics of the battery pack.

Because the voltage of the battery pack is neither above the first threshold nor below the second threshold, the voltage of the battery pack may fall within the voltage range of multiple battery chemistries. Continuing the previous example, if the measured voltage of the battery pack is 6.3 volts, the measured voltage would be with the voltage range for both the lithium battery pack (approximately 6 volts to approximately 8.7 volts) and the alkaline battery pack (approximately 5 volts to approximately 6.8 volts), so it may be indeterminate whether the battery pack has a lithium chemistry or an alkaline chemistry.

In alternative embodiments, the measured voltage may be compared to different numbers of thresholds. For example, the measured voltage may be compared against only one threshold, and the battery chemistry is determined based on whether the measured voltage is above or below that threshold. Similarly, the measured voltage may be compared against three or more thresholds, and the chemistry of the battery pack may be determined based on the relation of the measured voltage to the three or more thresholds. Further, while the method 2100 illustrates determining between two chemistries, alternative embodiments may be used to determining between three or more chemistries.

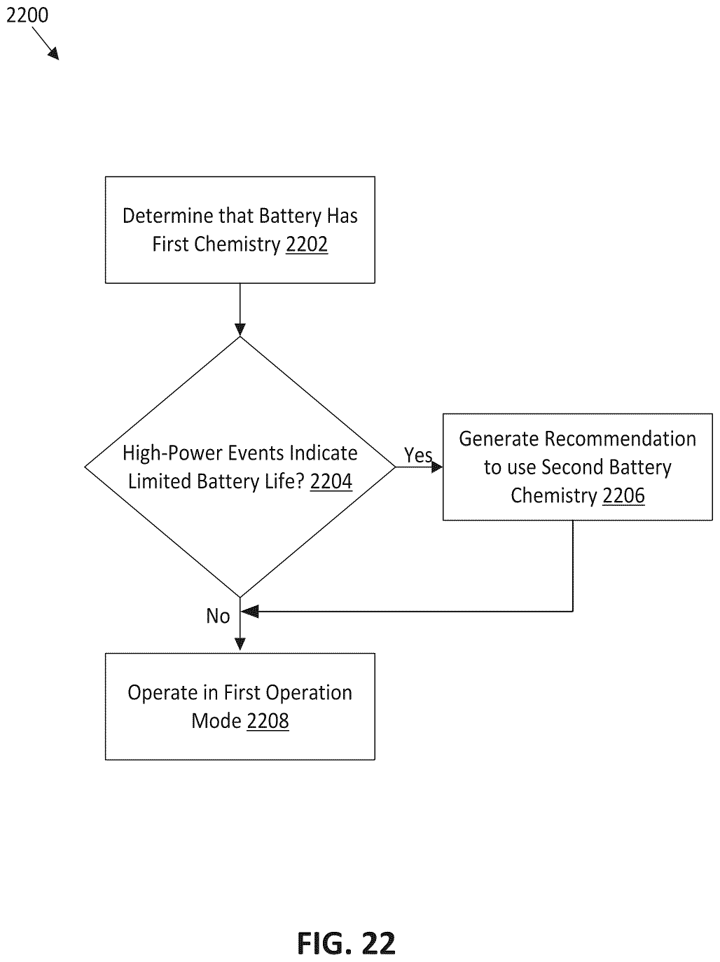

FIG. 22 illustrates a flowchart of an example method 2200 for operating an electronic lock in accordance with a first operation mode corresponding to a first chemistry associated with a first battery pack. The first battery pack may have a comparatively lower capacity as compared to a second battery pack that is useable with such an electronic lock. The method 2200 includes operations 2202, 2204, 2206, 2208, and may be performed by a processing unit of an electronic lock.

In the example shown, operation 2202 includes determining that the battery has a first chemistry, and therefore the electronic lock operates in a first operation mode, as described above in conjunction with FIGS. 19-21. While operating in the first operation mode, operation 2204 may include determining whether a sufficient number or type of events are performed at the electronic lock that may indicate lower battery life. For example, a history of operation events of the electronic lock may be analyzed to determine historical power usage of the electronic lock. In one particular example, a torque required by the motor to actuate a bolt may be determined, and if greater than a predetermined threshold torque, it can be determined that a greater amount of power may be required to move the bolt between locked and unlocked positions. In addition or in the alternative, it may be determined that the electronic lock is primarily communicating with external devices using WiFi, using Ultrawideband (UWB) communication, or otherwise is utilizing power-intensive features.

In any such instances, the electronic lock may generate, at operation 2206, a recommendation to use a battery that has a second battery chemistry (e.g., a higher capacity battery) as compared to the battery currently in use. For example, the electronic lock may generate an alert and communicate that alert to a mobile device (e.g., as described herein) as a notification that the electronic lock may have lower than expected battery life due to one or more high power consumption events or types of events occurring at the electronic lock, and recommending use of a different battery chemistry. In some instances, the notification generated at the mobile device may be presented within a mobile application (e.g., such as application 520 of FIG. 18), and may present the user with an option to acquire or purchase a battery pack having an extended capacity (e.g., according to a different battery chemistry).

If the electronic lock determines that a recommendation need not be generated, or in the alternative, after generation of such a recommendation, operation 2208 includes continuing to operate in accordance with the first operation mode, e.g., until a user elects to replace the battery having the first battery chemistry with another battery having a different battery chemistry.

Although in conjunction with FIG. 22, the operations 2202-2208 are described as occurring on the electronic lock, it is understood that one or more of these operations could occur on another device. For example, operations 2204, 2206-analyzing power consumption and generating recommendations regarding use of different types of batteries—may be performed at the mobile device itself (e.g., at application 520) or at a cloud account of the user, and pushed to the user as a notification either at the electronic lock or mobile device.

Embodiments of the present invention, for example, are described above with reference to block diagrams and/or operational illustrations of methods, systems, and computer program products according to embodiments of the invention. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

The description and illustration of one or more embodiments provided in this application are not intended to limit or restrict the scope of the invention as claimed in any way. The embodiments, examples, and details provided in this application are considered sufficient to convey possession and enable others to make and use the best mode of claimed invention. The claimed invention should not be construed as being limited to any embodiment, example, or detail provided in this application. Regardless of whether shown and described in combination or separately, the various features (both structural and methodological) are intended to be selectively included or omitted to produce an embodiment with a particular set of features. Having been provided with the description and illustration of the present application, one skilled in the art may envision variations, modifications, and alternate embodiments falling within the spirit of the broader aspects of the general inventive concept embodied in this application that do not depart from the broader scope of the claimed invention.

1. An electronic lock comprising:
an interior assembly including:
one or more electrical pins configured to electrically connect the electronic lock to a battery pack;
at least one processor; and
a memory communicatively connected to the at least one processor, the memory storing instructions which, when executed, cause the electronic lock to:
determine a chemistry of the battery pack; and
select an operating mode from among a plurality of operating modes based on the chemistry of the battery pack, wherein each of the plurality of operating modes is associated with a battery pack chemistry.

2. The electronic lock of claim 1, further comprising:
a latch assembly including a bolt movable between an extended position and a retracted position; and
a motor configured to move the bolt between the extended position and the retracted position,
wherein operation of the motor is based on the selected operating mode.

3. The electronic lock of claim 2, wherein an amount of power supplied to the motor to move the bolt between the extended position and the retracted position is based on the selected operating mode.

4. The electronic lock of claim 2, wherein a pulse-width modulation of the motor is based on the selected operating mode, and wherein a first operating mode from among the plurality of operating modes uses a different pulse width as compared to a second operating mode from among the plurality of operating modes.

5. The electronic lock of claim 1, wherein the memory further stores instructions which, when executed, cause the electronic lock to:
enter a low-power mode in response to a remaining power of the battery pack falling below a threshold,
wherein operation of the electronic lock in the low-power mode is based on the chemistry of the battery pack.

6. The electronic lock of claim 1, wherein to determine the chemistry of the battery pack includes to:
send a signal from the processor to the battery pack through at least one of the one or more electrical pins; and
determine the chemistry of the battery pack based on whether a response is received at the processor through the at least one of the one or more electrical pins.

7. The electronic lock of claim 1, wherein the interior assembly further includes:
a button,
wherein the chemistry of the battery pack is determined based on whether the button is pressed or not pressed.

8. The electronic lock of claim 1, wherein to determine the chemistry of the battery pack includes to:
measure a voltage of the battery pack; and
compare the measured voltage to one or more thresholds.

9. A method of operation of an electronic lock, the method comprising:
determining, at the electronic lock, a chemistry of a battery pack of the electronic lock based on a sensed signal associated with the battery pack; and
selecting an operating mode of the electronic lock from among a plurality of operating modes based on the chemistry of the battery pack, wherein each of the plurality of operating modes is associated with a battery pack chemistry.

10. The method of claim 9, further comprising:
operating a motor of the electronic lock to move a bolt between an extended position and a retracted position based on the selected operating mode.

11. The method of claim 10, wherein an amount of power supplied to the motor to move the bolt between the extended position and the retracted position is selected based on the selected operating mode, and wherein a first operating mode from among the plurality of operating modes uses a first amount of power and a second operating mode from among the plurality of operating modes uses a second amount of power different from the first amount of power, the first operating mode and the second operating mode being selected based on detection of different chemistries of a battery pack.

12. The method of claim 10, further comprising:
based on one or more historical operation events at the electronic lock, generating an alert recommending to switch to a different battery pack having a different chemistry, the different battery pack having a higher energy capacity than the battery pack used at the electronic lock during at least some of the historical operation events.

13. The method of claim 9, further comprising:
entering a low-power mode in response to a remaining power of the battery pack falling below a threshold,
wherein operation of the electronic lock in the low-power mode is based on the chemistry of the battery pack.

14. The method of claim 9, wherein determining the chemistry of the battery pack includes:
sending a signal from the electronic lock to the battery pack through at least one electrical pin of the electronic lock, the at least one electrical pin electrically connecting the electronic lock to the battery pack; and
determining the chemistry of the battery pack based on whether a response is received at the electronic through the at least one electrical pin.

15. The method of claim 9, wherein determining the chemistry of the battery pack includes:
determining whether a button in the electronic lock is pressed.

16. The method of claim 9, wherein determining the chemistry of the battery pack includes:
measuring a voltage of the battery pack; and
comparing the measured voltage to one or more thresholds.

17. A removable battery pack for an electronic lock, the battery pack comprising:
one or more batteries;
a connector configured to removably attach the battery pack to the electronic lock; and
one or more contacts electrically connectable to one or more pins on the electronic lock,
wherein a chemistry of the battery is used to determine an operating mode of the electronic lock.

18. The battery pack of claim 17, the battery pack further comprising:
one or more controllers,
wherein the one or more controllers are configured to transmit a response to a signal received from the electronic lock through the one or more contacts, the response used by the electronic lock to determine the chemistry of the battery pack.

19. The battery pack of claim 18, wherein the one or more controllers are further configured to measure a power into and out of the battery pack.

20. The battery pack of claim 17, wherein the one or more batteries are lithium batteries.
